(19) United States
(12) Patent Application Publication
(10) Pub. No.: US 2017/0005235 A1
(43) Pub. Date: Jan. 5, 2017

(54) LIGHT EMITTING DIODE, PHOTODIODE, DISPLAYS, AND METHOD FOR FORMING THE SAME

(71) Applicant: Stephen Y. CHOU, Princeton, NJ (US)

(72) Inventors: Stephen Y. Chou, Princeton, NJ (US); Wei Ding, Princeton, NJ (US)

(73) Assignee: Princeton University, Princeton, NJ (US)

(21) Appl. No.: 15/100,101

(22) PCT Filed: Nov. 28, 2014
(86) PCT No.: PCT/US2014/067829

§ 371 Date: May 27, 2016

Related U.S. Application Data
(60) Provisional application No. 61/909,644, filed on Nov. 27, 2013.

(51) Int. Cl. H01L 33/46; H01L 27/146; H01L 31/12; H01L 33/38; H01L 51/52; H01L 27/32; H01L 51/56; H01L 27/15; H01L 31/0232

(52) U.S. Cl. CPC H01L 33/465; H01L 27/156; H01L 27/14643; H01L 31/125; H01L 31/02327; H01L 51/5265; H01L 27/3234; H01L 51/56; H01L 33/38; H01L 51/5209; H01L 51/5225; H01L 2251/558; H01L 2933/0016; H01L 2933/0025

(57) ABSTRACT

The present invention is related to solid state light emitting diodes (LEDs), photodetector/photovoltaic devices, displays, applications and methods for making the same. As demonstrated experimentally, the LEDs, as disclosed herein, have high light emission efficiency, high contrast, high brightness, low ambient light reflection, low light glare, and a tunable display viewing angle. The same LED disclosed here can be used as high efficiency displays and high efficiency photovoltaic device or photodetectors. This means that the same device, where used in array form, can be used as the display (LED operation mode) and power supply (photovoltaic device mode) and camera (photodetector and imaging mode).

### CROSS-REFERENCES TO RELATED APPLICATIONS

This application claims priority to U.S. provisional application No. 61/909,644, filed on Nov. 27, 2013, the entire content of which is incorporated herein by reference.

### STATEMENT REGARDING FEDERALLY SPONSORED RESEARCH

This disclosure was made with United States government support under Grant awarded by the Defense Advanced Research Project Agency (DARPA). The United States government has certain rights in this disclosure.

### FIELD OF THE DISCLOSURE

The present disclosure generally relates to the field of electronic devices and, more particularly, relates to light emitting diodes, photodiode, displays, applications, and methods for forming the same.

### BACKGROUND

In both solid-state lighting and display applications, there is a great need to have a light emitting device (LED) that has a low reflection and/or scattering to the ambient light that are impinged (incident from outside) upon to the LED, and that have a high efficiency to generate light inside the LED and high efficiency to radiate the light inside the LED to outside.

However, conventional LEDs often fail to provide such low reflection and low scattering. Further, conventional LED structures may improve only some of the optical performances, often at the expenses of degrading the others.

For example, one method for enhancing light extraction (one key requirement for LED) is light scattering/reflection using micro/nano-patterned surfaces/interfaces and/or metal mirrors. Such a method often significantly increases the ambient light reflection, hence degrading the contrast. Such ambient light reflection problem is particularly serious in OLEDs (which use metallic high-reflective backplanes) or high light extraction inorganic LEDs (flip-chip with metallic high reflective-mirror). Existing methods for good contrast include certain methods that absorb the ambient light (e.g. circular polarizers, light absorbing layers, destructive-interference buffer layers, and low light reflection black cathode). However, such methods often also degrade the light extraction substantially. The degradation to the light extraction is often as large as a factor of 2 (i.e. losing a half of the total light that is otherwise being extracted). In other words, existing LED structures cannot have high light extraction and high ambient light absorption (i.e. low ambient light reflection) at the same time. The existing LED structures are either a good light radiator or a good ambient light absorber, but not both.

Another example, resonant-cavity LEDs with dielectric mirrors can be a good light radiator and absorber. However, such properties of the resonant-cavity LEDs only exist in a wavelength range of a few nanometers and in a particular direction. Thus, the resonant-cavity LEDs often suffer from similar low contrast and large glare as other existing LED structures in display applications. For LEDs, it requires a good radiator (for emitting light) and absorber (for antireflection) over a broad band.

Another example, in existing LEDs, a viewing angle is fixed by the Lambertian radiation pattern unless lenses or resonant cavities are used. Further, the ambient light reflection often follows Fresnel's law, hence having large glare.

Another example, currently the largest usage of displays is in hand-held devices. Displays on hand-held devices are often viewed at a fixed angle and are often used in bright ambient light. Thus, factors such as ambient light absorption, contrast, viewing angle, image sharpness, brightness and low-glare may become even more important than light extraction. However, most of the existing LED structures fail improve all these factors together.

The invented methods and structures in the disclosure are directed to solve one or more problems set forth above and other problems. Clearly, the inventions in the present disclosures have many applications as further discussed in the disclosure.

### BRIEF SUMMARY OF THE DISCLOSURE

This application is related to the method for enhancing and controlling the efficiency, contrast, viewing angle and brightness of light emitting diodes (LEDs), and display and making of the same.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the disclosure.

FIG. 1 depicts a structure diagram of an exemplary LED during operation in accordance with various disclosed embodiments;

FIG. 2a-2d depict exemplary structures of a MESH layer in accordance with various disclosed embodiments;

FIG. 3 depict exemplary structures of a light-emitting material layer in accordance with various disclosed embodiments;

FIG. 4a-4c depict exemplary structures of cavities in accordance with various disclosed embodiments;

FIG. 5a-5c depict exemplary structures of cavities in accordance with various disclosed embodiments;

FIG. 6 depicts a structure of an exemplary cavity in accordance with various disclosed embodiments;

FIG. 7 depicts a flow diagram of an exemplary method for forming an LED in accordance with various disclosed embodiments;

FIG. 8a-8f depicts a structure diagram of an exemplary LED at various stages during a fabrication process in accordance with various disclosed embodiments;

FIG. 9a depicts an exploded view of an exemplary PlaCSH-OLED in accordance with various disclosed embodiments; and

FIG. 9b depicts an energy band diagram of the PlaCSH-OLED depicted in FIG. 5A in accordance with various disclosed embodiments;

FIG. 9c depicts an exemplary fabrication process of the PlaCSH-OLED depicted in FIG. 5A in accordance with various disclosed embodiments;

FIG. 9d depicts a scanning electron microscopy (SEM) image of an exemplary MESH layer in accordance with various disclosed embodiments;

FIG. 9e depicts a cross-sectional SEM image of an exemplary PlaCSH-OLED in accordance with various disclosed embodiments;

FIG. 9f depicts an exemplary large area roll-to-roll flexible mold for a MESH layer in accordance with various disclosed embodiments;

FIG. 9g depicts green light emission from an exemplary PlaCSH-OLED in accordance with various disclosed embodiments;

FIG. 9h depicts ambient light reflection of a reference ITO-OLED;

FIG. 9i depicts ambient light reflection of an exemplary PlaCSH-OLED in accordance with various disclosed embodiments;

FIGS. 10a-10d depict measured electro-luminance (EL), J-V, Luminous Emittance and EQE of PlaCSH-LEDs and ITO-LEDs in accordance with various disclosed embodiments;

FIGS. 11a-11c depict angular distribution of electro-luminance (EL) of PlaCSH-OLED and ITO-OLEDs in accordance with various disclosed embodiments;

FIGS. 12a-12e depict measured angular distribution of electro-luminance (EL) of PlaCSH-OLED and ITO-OLED in accordance with various disclosed embodiments;

FIGS. 13a-13f depict measured angle and polarization dependence of ambient light reflectance for PlaCSH-OLEDs and ITO-OLEDs in accordance with various disclosed embodiments;

FIGS. 14a-14c depict measured contrast of PlaCSH-OLEDs, ITO-OLEDs and DMD-OLEDs in accordance with various disclosed embodiments; and

FIGS. 15a-15j depict numerical study of radiation and absorption properties of PlaCSH-OLED and ITO-OLED in accordance with various disclosed embodiments.

### DETAILED DESCRIPTION

The following detailed description illustrates some embodiments of the invention by way of example and not by way of limitation. Reference will now be made in detail to exemplary embodiments of the disclosure, and some of them are illustrated in the accompanying drawings. Subtitles are given for assisting the reading only and should not be construed as limitation to the description of the invention in the present disclosure.

The present invention is related to solid state light emitting diodes (LEDs), photodetector/photovoltaic devices, displays, applications and methods for making the same. As demonstrated experimentally, the LEDs, as disclosed herein, have high light emission efficiency, high contrast, high brightness, low ambient light reflection, low light glare, and a tunable display viewing angle. The same LED disclosed here can be used as high efficiency displays and high efficiency photovoltaic device or photodetectors. This means that the same device, where used in array form, can be used as the display (LED operation mode) and power supply (photovoltaic device mode) and camera (photodetector and imaging mode).

The present inventions are built on a previous disclosure, described in an application filed by the same inventors, PCT/US2012/063623 (WO2013/067541A1) filed on Nov. 5, 2012, which application is incorporated by reference herein for all purposes. The present disclosure focuses on certain aspects of new improvements over the previous disclosure.

### DEFINITIONS

In certain embodiments, terms are referred to the following meanings.

Ambient Light. Ambient light refers to light generated outside an LED. A reflection of ambient light can affect a viewer seeing a light generated inside the LED and coming from the LED. The reflection of ambient light can be problematic, when a person is viewing a LED display at a bright light condition including, e.g., outside room in bright daylight).

Contrast is defined as

Contrast=(Lₒₙ+L_{ambient}×R_{L})/(L_{off}+L_{ambient}×R_{L}),

where Lₒₙ and L_{off} is the luminance of the “on” and “off” state, respectively. L_{ambient} is the ambient luminance, and R_{L} is the luminous reflectance.

Viewing Angle is defined as full-width at half maximum of angular distribution of light emission.

An organic LED or OLED refers to a LED where the light-emitting material layer of the LED is made of an organic material.

Broad band refers to “over large range of wavelength”, typically 50 nm wavelength or larger.

PlaCSH is an acronym of “plasmonic cavity with subwavelength hole-array” light emitting diode

PlaCSH-LED refers to PlaCSH light emitting diode.

PlaCSH-OLED refers to PlaCSH organic light emitting diode.

Subwavelength refers to a feature size of a structure is less than the wavelength of interest.

### PlaSCH LED Structures and Operation

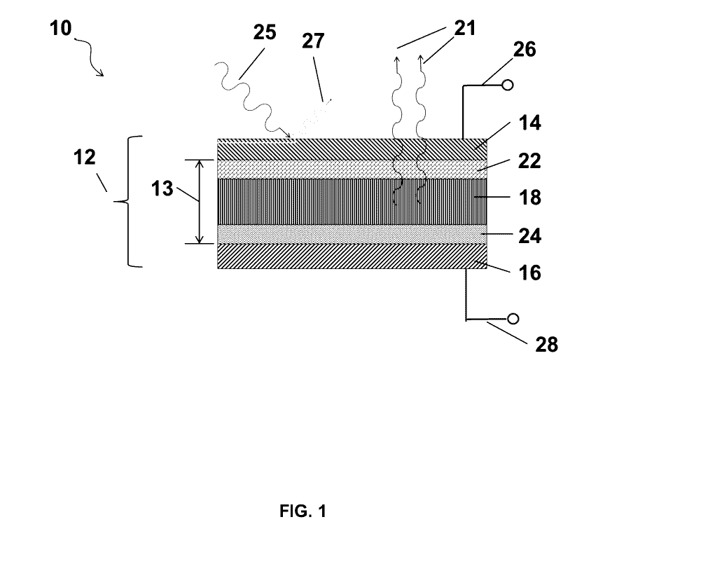

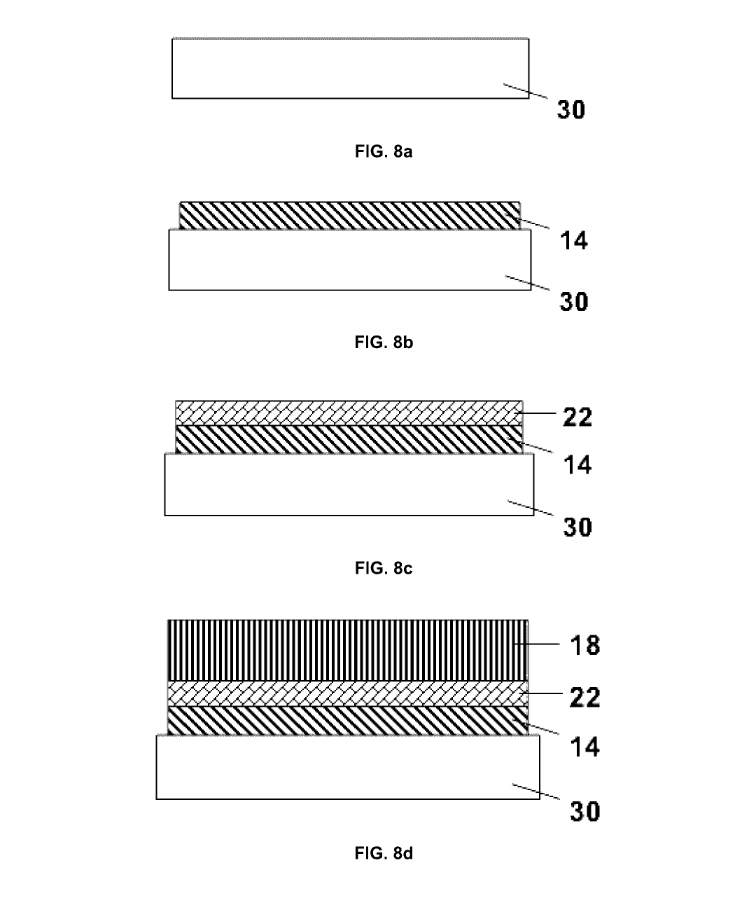

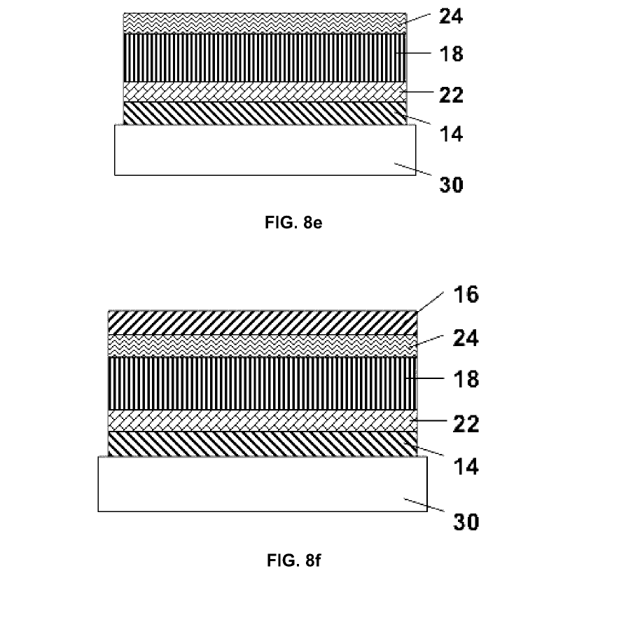

FIG. 1 depicts an exemplary structure embodiment of the LED of the invention in accordance with various disclosed embodiments. In FIG. 1, a structure of an PlaCSH-LED 10 (i.e. “plasmonic cavity with subwavelength hole-array light emitting diode (PlaCSH)-LED) or LED 10) comprises a photonic cavity antenna 12 (or a photonic resonant cavity antenna 12, cavity antenna 12, or cavity 12). The photonic cavity antenna 12 comprises the top metallic layer that is light transmissive 14, the backplane layer 16 (or bottom metallic layer 16), and the light-emitting layer 18 (or photon emission material layer 18, light-emitting material layer 18) that emits light (i.e. photons) 21 and is positioned between the top metallic layer 14 and the backplane layer 16. The light emission material layer 18 that can emit light 21 upon either flowing an electric current or irradiated by incoming photons. Besides being used as a part the photonic cavity antenna 12, the top metallic layer 14 and the bottom metallic layer 16, each serves as an electrode to the LED 10, by connecting to electric lead 26 and 28. The electrodes can supply electric current to the LED 10 for emitting light. The top metallic layer 14 that is light transmissionve allows light either radiates to outside of the cavity or transmits from outside to inside of the cavity. The photonic cavity antenna 12, the top metallic layer 14 and the bottom metallic layer 16 also can provide good cooling to the LED 10. The substrate 30 is optionally (see example in FIG. 8). The properties of the LED 10 depends on properties of the cavity 12.

Optionally, the light-emitting material layer 18 may have a top interface layer 22 on its top surface, and a bottom interface layer 24 on its bottom surface. The top and bottom interface layers 22 and 24 are for providing good adhesions between layers (serving as adhesion layer), blocking/transporting a particular electrical charge carrier type (serving as charge carrier blocking/transporting layer), or enhancing the performance of the cavity antenna (serving as a spacer). The spacer might be needed in a metallic photonic cavity to reduce certain quenching of light by metal.

One of the LED 10 operation is in the flowing way. (a) In the electrical current pumping mode, a voltage is applied between the top metallic layer 14 and the bottom metallic layer 16, through the leads 26 and 28, causing an electric current flowing through the light-emitting layer 18 to generate photons (i.e., light). The metallic photonic resonant cavity antenna 12 enhances the radiation from the photo-emission material and the extraction of light from the light-emitting material 18 inside of the cavity to the free space outside of the cavity antenna 12. The enhancement of light extraction means that for a given light-emitting material (and the same geometry) and a given voltage biasing condition, the LED with the cavity antenna radiates and extracts more light out to the free space (outside LED) than the LED without the cavity antenna. The light that cannot be extracted out will become the heat, which can significantly reduce the LED operation lifetime and performance (since performance is temperature dependent).

(b) In the optical pumping mode, a light is irradiated from outside of the LED 10 to inside to produce a light in the light-emitting material 18 (no electrical current is needed). In this operation mode, in addition to enhance the light extraction at emission wavelength, the cavity antenna 12 also enhance the light transmission at pumping wavelength from the outside of the cavity through the light transmissive electrode into the cavity (which means that light transmission will larger with the cavity than that just the light transmissive electrode alone without a cavity), and enhance the trapping and absorption of the pumping light inside of the cavity (due to the multiple light reflection inside the cavity).

When an ambient light 25 is incident on the surface 11 (near the top metallic electrode 14) of the LED 10, a part of the ambient light is reflected or scattered to form the reflected/scattered light 27, and a part of the ambient light (not drawn in FIG. 1) will be absorbed inside of the LED 10. One of special properties of the LED 10 is that the reflected/scattered light 27 is much smaller compared to the incoming ambient light 25. And LED 10 has such low reflected/scatted light over a wide bandwidth of the light wavelength (termed “broad band”). The small reflection/scattering are due the fact the LED 10 is a good absorber to the ambient light. A higher radiation of the light generated inside the LED 10 to outside and a small ambient light reflectivity by the LED 10 makes the LED 10 having an excellent contrast. Such high contrast are very important to many applications, including, not limited to, personal electric devices (e.g. smartphones).

In other words, when the top metallic layer 14, light emitting material 18, and the bottom metallic layer 16 form the cavity 12, the cavity 12 absorbs the ambient light more significantly higher than the sum of the ambient light absorption for each individual layer without the cavity 12, and the light reflectivity of the cavity 12 to the ambient light is significantly less than the sum of the ambient light reflectivity for each individual layer without the cavity 12.

The top metallic layer 14 can be made antiflection to itself ambient light, but the antireflection for the cavity 12 can be better than the top metallic layer 14 alone. Furthermore, the light goes through the top metallic layer 14 can significantly reflected by the backplane layer 16, but the cavity 12 traps the reflected light inside the cavity 12.

A system can comprise a plural of the LED 10 with each LED 10 being electrically biased either individually (independent with other LED 10's) or together or a combination of the two methods. A plural of the LED 10 can form a display device. The same plural of the LED 10 can used as camera (each LED 10 record a pixel) and as photovoltaic device to provide electrical power.

A PlaCSH can achieve various functions by utilizing certain unique properties of metals together with the cavity design. Metals have many unique properties over dielectric counterparts. One of the unique properties is the generation of surface plasmon polariton (SPP), which can, under certain conditions, enhance the light radiation rate (Purcell Effect), alter the radiation intensity and pattern, and improve the light extraction.

One aspect of the present disclosure is a new light-emitting diode (LED) structure that uses a PlaCSH, also referred to as “metallic photonic resonant cavity antenna”, “photonic resonant cavity antenna” or “cavity antenna”, to significantly enhance light extraction, ambient light absorption, contrast, brightness, viewing angle, image sharpness and low-glare. The PlaCSH can be used as a metallic photonic resonant cavity antenna to greatly enhance radiation from the light-emitting material and extraction of light from the light-emitting material inside the cavity to the free space outside of the cavity antenna. According to certain disclosed embodiments, the PlaCSH can include a metal mesh having a subwavelength pattern. The metal mesh can be light-transmissive and can be used for replacing indium-tin-oxide (ITO). In various embodiments, a layer that is “light-transmissive” can refer to a layer that can partially or can substantially completely transmit an incident light through the layer.

According to one aspect of the present disclosure, a photonic resonant cavity antenna of a PlaCSH-LED can include a metallic-mesh electrode with subwavelength hole-array (MESH) layer that is light-transmissive, a backplane layer, and a light-emitting material layer that is made of semiconductor and is positioned between the top metallic layer and the backplane layer for producing light.

One of the novelties of the present disclosure is that the PlaCSH-LED enhances both radiating out the light generated inside the PlaCSH (i.e. more efficient in emitting the light generated by the PlaCSH-LED) and absorbing the light of the same wavelength (or same wavelength range) coming from outside the PlaCSH (i.e. more efficient in absorption ambient light). Furthermore, the absorption to the ambient light is not only high, but also broad-band and omni acceptance. Such properties can lead to a high contrast in a LED display and can thus be extremely useful for LED displays.

Another novelty of the present disclosure is that the PlaCSH-LED has a viewing angle and light radiation angle distribution tunable by a cavity length and/or other parameters (e.g. the geometry and materials) of the PlaCSH-LED. In various embodiments, a cavity length can refer to a distance between the two metal electrodes of the PlaCSH-LED.

By tuning the parameters of the PlaCSH-LEDs, light emitted from the PlaCSH can be made to more focused into one direction or spread to a wider angle. For example, the PlaCSH-LEDs have exhibited up to 17 degree narrower or wider than an OLED without the PlaCSH (e.g. the ITO-OLEDs) having a nearly-fixed viewing angle. The viewing angle also can be tuned by using different metals and different nanostructures on the front and back electrode of LED.

Another novelty the PlaCSH-LEDs is that the PlaCSH-LED has a higher brightness to certain angle than a reference LED. A reference LED can refer to an LED that is the same as or similar to a PlaCSH-LED but has no PlaCSH. The brightness and the angle can be tuned by changing the structure geometry and materials of the PlaSCH-LED.

Another novelty the PlaCSH-LEDs is that the light radiation has a uniform color over all emission angles. Means good image sharpness in display applications.

Another novelty of the PlaCSH-LED is that it has broad-band, angular insensitive, similar strength of enhancement on light radiation from inside the cavity to outside and extraction from outside to inside. This property remains the uniform color over angles and image sharpness in display applications.

In one embodiment, this disclosure is related to a new LED of high-performance and the methods for making same. Various embodiments of the present disclosure can solve one or more challenges in a conventional LED. The various challenges can include, e.g., how to (a) enhance light radiation in light emitting material; (b) effectively extract the light from the inside of the light-emitting material to outside; (c) replace ITO transparent electrode; (d) enhance the ambient light absorption; (e) remain the uniform color over angles; (f) controlling the radiation pattern, angular distribution and viewing angle; (g) when pumped by a light source not by an electric current, achieve (i) high light transmission from the outside to inside of the LED and (ii) high light trapping and absorption in a very thin light-generating material of the LED to maximize the quantum efficiency; and (h) better cooling. In certain embodiments, quantum efficiency can refer to an efficiency of converting an incoming light to an emitted light by the light-generating material of the LED.

Our studies have shown that the LED 10 can have high (>90%) light absorption and trapping over a broad bandwidth and omni acceptance. Omni acceptance can refer to “nearly independent of incident light angle and polarization and with changes much smaller than Fresnel law”.

Another property of the LED 10 is that the same LED 10 used for light emitting can be used as a photodetector that detects the ambient light and generate electrical signal and power at the two electrode of the LED 10. LED 10 can be a high efficient photodetector due to its good ability of absorbing the ambient light. The ambient light absorbed by the LED 10 can create charge carriers (e.g. electrons and/holes). The photo-generated charge carriers can be transported to electrode 26 and 28, generating a voltage difference or an electric current between the electrode 26 and 28. The same device which can be used efficiently for light emitting and light detection have many advantages. For example, in smartphone or alike, the LED 10 can be used as display when in light emission mode, also as camera when in photodetector mode, as well as power source when in photodetector mode (like a photovoltaic device). The same LED 10 can be operated as a light emitting diode (LED) and a photodetector (for camera or power supply) either sequentially (i.e. as LED at one time and photodetector as the other time) or at the same time.

The same LED 10 disclosed here can be used as high efficiency displays and high efficiency photovoltaic device or photodetectors. This means that the same device, where used in array form, can be used as the display (LED operation mode) and power supply (photovoltaic device mode) and camera (photodetector and imaging mode). A plural of LED 10 operates in both light emitting mode and photon detection mode for imaging or supper supply.

The optical interaction between the top metallic electrode and back plane is essential to achieve high performance PlaCSH-LED; High performance means to (a) enhance light radiation in light emitting material; (b) effectively extract the light from the inside of the light-emitting material to outside; (c) enhance the ambient light absorption. The strong optical interaction requires a specific design of the PlaCSH's material and geometry, such as (a) optical distance (cavity length multiplied by refractive index) between the top and bottom electrodes, usually subwavelength (less than the radiation wavelength); (b) thickness of the two electrodes; (c) materials of the two electrodes; One of our findings shows that, with this strong optical interaction, more light can be transmitted through the top metallic electrode (to outside or inside depending on the light source), thus enhance the light extraction and trapping.

Another aspect of the present disclosure includes a method for forming the disclosed PlaCSH-LED. The method can include growing a light-emitting material layer using at least one of low temperature molecule beam epitaxy (MBE), sputtering, physical vapor deposition (PVD), chemical vapor deposition (CVD), thin film deposition, the film transfer-printing, and thin film spinning on.

The LED 10 can work for broad range of wavelength, regardless if it operates in LED (light emitting mode) or photodetction mode (for power supply or camera). The operating wavelength of the LED 10 can be from 30 nm to 40,000 nm. Since it would be hard to have one of the cavity 12 design to work for the entire possible wavelength range, a preferred working range can be 50 to 100 nm, above 100 to 300 nm, above 300 nm to 400 nm, above 400 nm to 800 nm, above 800 nm to 1,600 nm, above 16,000 nm to 4,000 nm, above 4,000 to 10,000, and above 10,000 to 40,000 nm.

### Light Emitting Layer (18) and Interface Layer (22, 24)

The light-emitting layer 18 comprises one or more of a single material 52, a mixture of a plurality of materials 54, multiple layers of a plurality of materials 56. For example, the single material 52 can include any appropriate single material often used for LEDs. The materials mixture 54 can include a mixture of a hole material and an electron material. The materials mixture 54 can include a mixture of different polymers domains (also referred to “bulk-heterojunction layer”) for polymer LEDs. The multi-layer stacking structure 56 can include a PN junction of any appropriate semiconductors either inorganic or organic.

The light-emitting material layer 18 can be made of inorganic and/or organic light-emitting materials that is either crystalline, polycrystalline, amorphous, a hetero-mixture, or a combination thereof. In various embodiments, a hetero-mixture can refer to a mixture having difference material mixed together as small grains. The light-emitting material layer has a thickness ranging from about 2 nm to about 700 nm, or from about 1 nm to about 100 nm.

For example, the inorganic light-emitting materials can include III-V materials (e.g., GaAs, InP, AlGaAs, GaN, (AlGa)InP), II-VI material (e.g., CdZnSe—CdMgZnSe, ZnSe), nano-scale materials (e.g., quantum dots of cadmium selenide, cadmium sulfide, indium arsenide, and indium phosphide), and combination thereof.

For example, the organic light-emitting materials can include small molecule, e.g., dye (e.g., phosphorescent dyes), p-type conjugated molecules (e.g., tetracene and pentacene), n-type conjugated molecules (e.g., fullerene derivatives, such as [6,6]-phenyl-C61-butyric acid methyl ester (PCBM)). The organic light-emitting materials can further include polymers, e.g., poly(1,4-phenylene vinylene) (PPV) (e.g., MEH-PPV, MDMO-PPV, BCHA-PPV), poly(1,4-phenylene) (PPP), polyfluorenes (PFO) (e.g., poly(9,9-dioctylfluorene)), poly(thiophenes) (e.g., regiorandom poly(3-octylthiophene)), nitrogen-containing polymers (e.g., 1,3,4-Oxadiazole), water-soluble LEPs (e.g., sulfonated PPV).

In other examples, the light-emitting material layer 18 can be made of a semiconductor selected from a material that is crystal, amorphous, polycrystalline, inorganic, organic, a polymer, Gallium Arsenide (GaAs), Gallium Nitride (GaN), Gallium Indium Nitride (GaInN), Alumium Nitride (AlN), Silicon (Si), Germanium (GE), and/or any appropriate semiconductor that emits photons.

The light-emitting material layer 18 can be made of a host-guest phosphorescent organic (e.g., small molecule) system. The light-emitting material layer 18 can include one or more hole transport layers (e.g., 4,4′,4″-tris(carbazol-9-yl) triphenylamine (TCTA)), one or more electron transport layers (e.g., 4,7-diphenyl-1,10-phenanthroline (BPhen)), and/or can be doped with phosphorescent dye (as fac-tris(2-phenylpyridine) iridium(III) [Ir(ppy)3]).

The light-emitting material layer 18 can have a thickness that is optimized for radiating light from inside of the cavity antenna to outside of the cavity antenna and for ambient light trapping from outside of the cavity antenna to inside of the cavity antenna.

Typically, for visible radiation wavelength around 500 nm to 600 nm, and ambient light absorption wavelength 400 nm to 900 nm, the thickness of the light-emitting material layer 18 can range from about 20 nm to about 400 nm, which depending upon the light wavelength. The top metallic layer 14 can have a period of the hole array ranging from about 40 nm to about 500 nm, and a thickness ranging from about 5 nm to about 100 nm. The backplane layer 16 can have a thickness ranging from about 50 nm to about 500 nm and an average reflectance greater than about 90%.

The first interface layer 22 can be used for providing good adhesion between layers. That is, the first interface layer 22 can serve as adhesion layer. The first interface layer 22 can further block and/or transport a particular electrical charge carrier type (serving as charge carrier blocking/transporting layer), or enhance the performance of the cavity antenna (serving as a spacer). The spacer might be needed in a subsequently-formed metallic photonic cavity to reduce certain quenching of light by metal. The spacer might also be needed to control the photonic density of states, electrical field distribution, magnetic field distribution inside the cavity and enhance the radiation efficiency of the material, light extraction and trapping.

In one embodiment, the first interface layer 22 can contain the top metallic layer 15 inside itself. For example, one typical structure can be the first interface layer 22-1/top metallic layer/the first interface layer 22-2. 22-1 and 22-2 can be different in thickness and material.

For example, the first interface layer 22 can include a charge carrier transporting/blocking layer, an optical spacer layer, an adhesion layer, or a combination thereof. The charge carrier transporting/blocking layer can include poly(3,4-ethylenedioxythiophene) poly(styrenesulfonate) (PEDOT:PSS), fullerene derivatives (e.g., Cao), aluminum tris (8-hydroxyquinoline)(Alq3), lithium fluoride (LiF), calcium (Ca) and titanium oxide (TiOₓ), or a combination thereof. The optical spacer layer can include transition metal oxide of zinc oxide (ZnO), titanium oxide (TiOₓ), molybdenum dioxide (MoO₂), or a combination thereof. The adhesion layer can include titanium (Ti), aluminum (Al), chromium (Cr), platinum (Pt), polyimide, or a combination thereof.

For example, the second interface layer 24 can include a charge carrier transporting/blocking layer, an optical spacer layer, an adhesion layer, or a combination thereof. The charge carrier transporting/blocking layer can include poly(3,4-ethylenedioxythiophene) poly(styrenesulfonate) (PEDOT:PSS), fullerene derivatives (as C₆₀), aluminum tris (8-hydroxyquinoline)(Alq3), lithium fluoride (LiF), calcium (Ca) and titanium oxide (TiOₓ). The optical spacer layer can include transition metal oxide, e.g., zinc oxide (ZnO), titanium oxide (TiOₓ), and molybdenum dioxide (MoO₂). The adhesion layer can include, e.g., titanium (Ti), aluminum (Al), chromium (Cr), platinum (Pt) and polyimide.

Typically, the thickness of interface layer 22, 24 can range from about 0.1 nm to about 100 nm, which depending upon the function and light wavelength. For visible light emission, the interface layer can range from 0.1 nm to 50 nm when serving as charge carrier transporting/blocking layer, 0.1 nm to 5 nm when serving as an adhesion layer, 10 nm to 100 nm when serving as an optical spacer layer.

The top metallic layer can further play a role of replacing the conventional ITO front transparent electrode. During operation of a PlaCSH-OLED, holes and electrons can be supplied by the metallic-mesh electrode and the back electrode (e.g., made of Al), respectively. The holes and electrons can be recombined in the light emitting materials to generate photons (i.e., light). In certain embodiments, a PlaCSH-OLEDs can be fabricated face-down with MESH next to the substrate through which the light comes out.

### Top Metallic Layer 14

The top metallic layer 14 is critical to the propertied of the LED 10. Beside many functions, the two key functions of the top metallic layer 14 is to (a) transmit light through (forming a light-transmissive electrode to allow light transmission while supplying either electric voltage or current. That is, the top metallic layer 14 can be a transparent conducting electrode), and (b) when coupled with the bottom metallic 16 and the light emitting layer 18, the light emission generated inside the LED 10 to outside and enhance is enhanced, the resultant reflectivity of the LED 10 to the ambient light is less than the sum of the reflectivity from each individual without the cavity 12, and the ambient light trapping inside of the LED 10 is enhanced. The function of the top metallic layer 14 are related to the geometry/structures and materials.

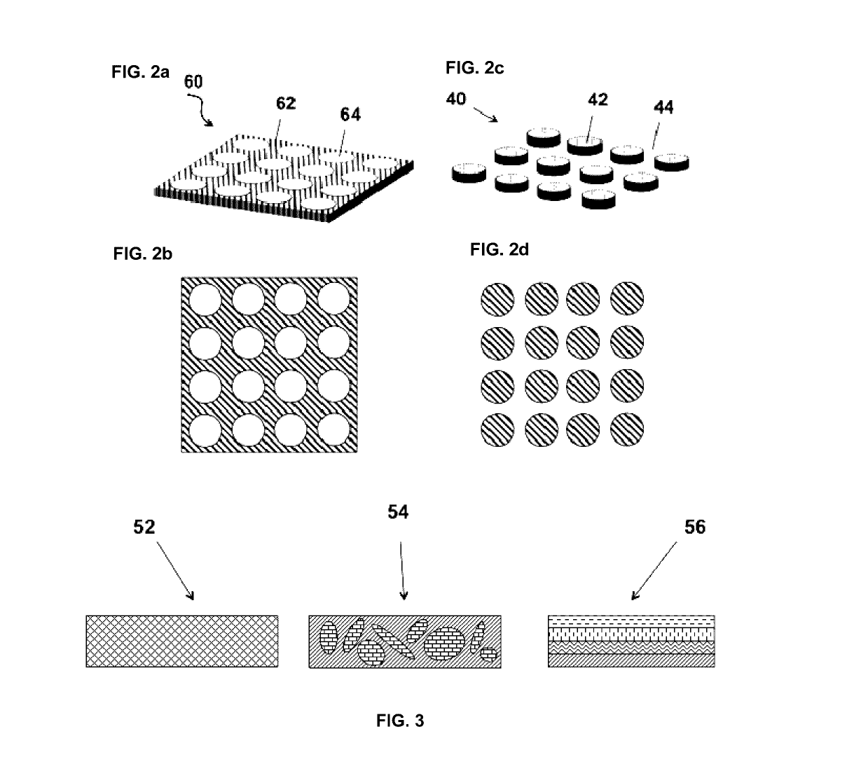

In one embodiment, as depicted in FIG. 2a, the top metallic layer 14 comprises a thin continuous metallic layer with a hole 64 or a plural of holes 60. An example is the metallic mesh. For a plural of holes 60, the size of each hole 64 and a separation or distance 62 between two adjacent holes are preferably less than the wavelength of the transmitted light, which is termed “subwavelength”. In certain embodiments, the subwavelength nature of the features in the metallic material layer 60 can be essential to the desired photonic property.

The holes (aperture) 64 can have any shape comprising round, rectangle, polygon, a triangle, holes with random edges, or a superposition and/or combination thereof. The holes 64 can be periodic and aperiodic. The size and the shape of each hole can be the same as or different from other holes 64. To create a broad band response of PlaCSH in radiation and absorption of light, the shape of the hole 64 is preferably to have a complex shape, rather than a perfect round shape.

In another embodiment, the structure of the top metallic layer 14 also can be in form of an array of metallic material disks 40. Each disk 42 is subwavelength and has a shape selected from the group consisting of round hole, polygon, triangle, holes with random edges or a superposition of one or more thereof. The distance between the disks 44 is also subwavelength.

Each disk 42 can have a subwavelength size and have a shape that is round hole, polygon, triangle, holes with random edges, or a superposition and/or combination thereof. A distance 44 between two adjacent disks can also be subwavelength. The metallic material disks 40 can be periodic and aperiodic. The size and the shape of each disk 42 can be the same or different from other disks 42, as long as most of the disks 42 are subwavelength.

Optical properties of the metallic material disk array can function similar as that of the metallic material mesh (i.e., the hole array) in transmitting the light and in working as a mirror for the photonic cavity. But the disk array cannot conducting electric current to be used as an electrode for the LED 10. To overcome the problem, a thin electrical conducting layer, which will not significantly affect the optical property of the photonic cavity can be deposited on the disk array. One example is to deposit a thin ITO film on the disk array for visible light range. In some cases, an ultra-thin metal film can be used with the disk array. The thickness of the top metallic layer 14, whether using in a hole array or a disk array, is from about 1 nm to about 150 nm, with one embodiment having a preferred thickness of about 15 to about 40 nm.

The material for the top metallic layer 14 comprise a metallic material, a mixture of metallic materials. The top metallic layer 14 can have a single-structure made of one or more metallic materials, or a multi-layer structure made of one or more metallic materials. The property of metallic material is essential to the desired property of the photonic resonant cavity antenna (e.g., enhanced light extraction, transmission and trapping).

In various embodiments, when a material is referred to as “metallic”, the material not only conducts electric current, but also behaves like a metal under a light radiation, when the wavelength (frequency) of the light is longer (lower) than the plasmon wavelength (frequency) of the metal, so that the free electrons in the metal can respond to the oscillation of incoming light, strongly reflecting the light backward. However, if the wavelength (frequency) of the incoming light is shorter (higher) than the plasmon wavelength (frequency) of the metal, so that the free electrons in the metal cannot respond to the oscillation of incoming light, it behaves like a dielectric and becomes transparent to the incoming light.

In one example, bulk gold, having a plasmon wavelength at about 540 nm, can be “metallic” and light will strongly reflected back for the light with a wavelength longer than about 540 nm. However, bulk gold can become transparent to the incoming light if the light has a wavelength much shorter than about 560 nm.

In another example, ITO can have a plasmon wavelength of about 1.8 um. Therefore, at a visible light wavelength (400 to 700 nm), an ITO layer, although electrical conducting, can be transparent and not metallic. In various embodiments, photons and light can be interchangeable in the description.

Depending upon the working photon wavelength (i.e., a photon wavelength of light emitted by the LED, or of the light absorbed from outside of the LED during operation of the LED), the top metallic layer 14 can be made of a material chosen from the materials that are metallic in the working photon wavelength. For example, when the working photon wavelength is equal to or longer than a visible light wavelength, the metallic materials can be selected from gold, copper, silver, aluminum, or a mixture thereof, or an alloy made of any metals thereof. The top metallic layer 14 can include a multi-layer stacking structure. When the working photon wavelength is equal to or longer than a near- or mid-infrared wavelength, the metallic materials can be selected from ITO or certain metal oxides. In addition, silicon can become metallic when the working photon wavelength is in certain light wavelength range.

Furthermore, the metallic materials also needs to be chosen by considering material work function matching of the LED. That is, the selection of metallic material needs to consider the energy band matching between the materials for the top metallic layer 14 and a subsequently formed light-emitting layer.

In one example, when the working photon wavelength is equal to a visible light wavelength, ITO can be deposited on the disk array 40. In another example, a ultra-thin metal film can be used with the disk array 40. The thickness of the top metallic layer 14, whether including a hole array or a disk array, can range from about 1 nm to about 150 nm. In one embodiment, the top metallic layer 14 can have a thickness ranging from about 15 to about 40 nm. In another embodiment, the hole array or the disk array of the top metallic layer 14 can have a period ranging from about 50 nm to about 400 nm for visible light emission, and the top metallic layer 14 can have a thickness ranging from about 10 nm to about 80 nm.

### Bottom (Back) Metallic Layer 16

The backplane layer 16 can be made of a metallic material, a mixture of metallic materials, or multilayers of metallic materials. The backplane layer 16 can be flat (i.e., smooth) or structured. The property of metallic material of the backplane layer 16 can be essential to the desired property of the photonic resonant cavity antenna, e.g., for enhanced light extraction, transmission and trapping.

Depending upon the working photon wavelength, the backplane layer 16 can be made of a material chosen from the materials that are metallic in the working photon wavelength. For example, when the working photon wavelength is equal to or longer than a visible light wavelength, the metallic materials can be selected from gold, copper, silver, aluminum, platinum, nickel, zinc, titanium, palladium, lithium, calcium or a mixture thereof, or an alloy made of any metals thereof. The backplane layer 16 can include a multi-layer stacking structure. When the working photon wavelength is equal to or longer than a near- or mid-infrared wavelength, the metallic materials can be selected from ITO or certain metal oxides. In addition, silicon can become metallic when the working photon wavelength is in certain light wavelength range.

For the photonic property of the cavity, the thickness of the backplane layer 16 can be insignificant, because the photonic role of the bottom metallic layer is to reflect the photons. However, the thickness of the backplane layer 16 can be significant for fabrication, flexibility, and cooling. For easy fabrication or flexibility, the thickness of the backplane layer 16 can range from about 5 nm to about 5 microns. Furthermore, the selection of metallic material needs to consider the energy band matching between the materials for a metallic layer and an active layer.

The bottom metallic layer 16 comprises a metallic material, a mixture of metallic materials, or multilayers of metallic materials. The bottom metallic layer can be flat or structured. The property of metallic material is essential to the desired property of the photonic resonant cavity antenna (e.g., enhanced light extraction, transmission and trapping).

By a material being “metallic”, it means that the material not only conducts electric current, but also behaves like a metal under a light radiation, when the wavelength (frequency) of the light is longer (lower) than the plasmon wavelength (frequency) of the metal, so that the free electrons in the metal can respond to the oscillation of incoming light, strongly reflecting the light backward. However, if the wavelength (frequency) of the incoming light is shorter (higher) than the plasmon wavelength (frequency) of the metal, so that the free electrons in the metal cannot respond to the oscillation of incoming light, it behaves like a dielectric and becomes transparent to the incoming light. For examples, bulk gold, having a plasmon wavelength at about 540 nm, is “metallic” and light will strongly reflected back for the light with a wavelength longer than about 540 nm; but becomes transparent to the incoming light if the light with a wavelength is much shorter than 560 nm. Other example is that indium-tin-oxide (ITO) has a plasmon wavelength at about 1.8 um, hence at a visible light wavelength (400 to 700 nm) an ITO layer, although electrical conducting, is transparent and is not metallic. (Note the photons and light are interchangeable in the description).

### Photonic Cavity (PlaCSH) 12

The cavity 12 is a key element assembly responsibly to the properties and performances of the LED 10.

The cavity length 13 refers to a total thickness of the light-emitting material and any interface layers between the two cladding layers; namely, the cavity length is the inner distance between the top metallic electrode 12 and the bottom metallic layer 16.

In certain embodiments, for the LED 10, the cavity 12 may serve as an antenna that efficiently radiate light generated inside the cavity 12 to outside and at same time efficiently absorbing the light generated from the outside to inside of the cavity 12. For a function of high performance LED and photodiode, such high radiation and high absorption should be broadband, namely covering a broad range of wavelength range.

The properties of cavity 12, particularly the light emitting from the cavity and/or the absorption of the light coming from outside of the cavity, can be controlled the methods that comprising the control of i. localized surface plasmonic resonance (LSPR) due to the subwavelength cavity; ii. localized surface plasmonic resonance (LSPR) due to MESH self; iii. surface plasmon resonance (SPR) due to MESH; iv. surface plasmon resonance (SPR) due to metal backplane; v. TE/TM waveguide mode due to the cavity; All this modes (i-v) absorb in different wavelength band. In certain embodiments, the main radiation enhancement come from (i) LSPR from cavity.

Thus, to remain good in the radiation, we should remain the localized surface plasmonic resonance from the subwavelength cavity matching the radiation wavelength and having strong coupling efficiency between the mode and the radiation light. To enhance the total absorption, we should engineer all the other modes to 1) cover wider wavelength band; ii. enhance the modes coupling strength to absorb more ambient light from outside and in other wavelength range.

Certain examples of cavity's light property control are: by changing the cavity length from 80 nm to 200 nm in a PlaCSH-OLED made by polymer (poly[2-methoxy-5-(2-ethylhexyloxy)-1,4-phenylenevinylene), the external quantum efficiency (EQE) changes from 1.2% to 2.35%. PlaCSH-OLED with 100 nm cavity length has the highest EQE of 2.35% in this example.

Total cavity length influences both the radiation and absorption. There is a best value for highest absorption, but this value might not give the highest radiation. This value is usually subwavelength and has a thickness around 30-300 nm for organic (polymer or small molecule) LEDs;

One preferred embodiment is that the cavity length divided the average index is between one fifth to half of the wavelength of the emitted or absorbed light of the LED 10 measured in vacuum.

Remaining the total cavity length (thus the high absorption), radiation can be tuned and enhanced by the emission layer position inside cavity; usually emission layer can be put 10-150 nm away from metal backplane to give the highest radiation for organic (polymer or small molecule) LEDs;

MESH's period is one key parameter to determine the localized surface plasmonic resonance (LSPR) of the subwavelength cavity; Usually longer wavelength emission need a larger period; For example, 500-700 nm radiation emission wavelength prefer a MESH period of 100-450 nm;

MESH's thickness has an optimized value. Too thick MESH has more optical ohmic loss, thus highly reduces the radiation (but enhance the absorption). Too thin MESH has poor electrical conductance, degrading the electrical properties and radiation. And optimized MESH's thickness is 5-50 nm for organic (polymer or small molecule) LEDs;

MESH and Backplane's material; The material influence the cavity's modes. For backplane, high reflective (at least for radiation wavelength) metal is preferred as aluminum or silver. For MESH, the radiation wavelength and plasmon resonance of the material should be considered together. For example, Gold, Silver works in visible range, but not in UV range.

Backplane's thickness; Except for special applications as transparent LED windows, thickness of backplane should be larger than material's evanescent wave decay length. For example, larger than 50-100 nm for aluminum backplane. In such a case, a typical length of the cavity 12 for a light-emitting material layer 18 made of polymer light-emitting materials can range from about 50 nm to about 300 nm. These parameters are critical for the enhancement and the working band. An improper design (mismatch the device working band with working wavelength) may greatly reduce the enhancement and working band.

Scaling

Scaling with the wavelength. The preferred parameters in (1) to (6) above are for the light radiation and light absorption wavelength from 500 nm to 650 nm. For the light wavelength outside the 500 to 650 nm range, the preferred parameters should be scaled approximately linearly with the wavelength. For example, if original preferred parameter is a for the wavelength b, then the preferred parameter x for a wavelength y is approximately equal to a times y over b (i.e. x=a*(y/b)).

Scaling with active layer's refractive index. The preferred parameters in (1) to (6) above are for the active layer's optical refractive index 1.5-2.5 from 500 nm to 650 nm wavelength range. For other material with different optical refractive index (or same material in other wavelength range, thus has different optical refractive index), the preferred parameters (especially the cavity length) should be scaled approximately inverse linearly with the refractive index. For example, if original preferred parameter is a for the refractive index c, then the preferred parameter x for a refractive index z is approximately equal to a times c over z (i.e. x=a*(c/z)).

### Another Embodiments of PlaSCH-LED Structure

Although during the exemplary fabrication process of the PlaCSH-LED (the LED 10) as described in FIG. 5 and FIGS. 2A-2F, the top metallic layer 14, the first interface layer 22, the light-emitting material layer 18, the second interface layer 24, and the backplane layer 16 are fabricated sequentially, the sequence of fabrication is not limited in the present disclosure. For example, on a carrier, the backplane layer 16 can be fabricated first, and the top metallic layer 14 can be fabricated last. When a substrate is needed, the formed PlaCSH-LED can be transferred to the substrate.

Further, one or more of the top metallic layer 14, the first interface layer 22, the light-emitting material layer 18, the second interface layer 24, and the backplane layer 16 can be fabricated on a separate carrier or platform and then transferred onto an appropriate layer to form the PlaCSH-LED.

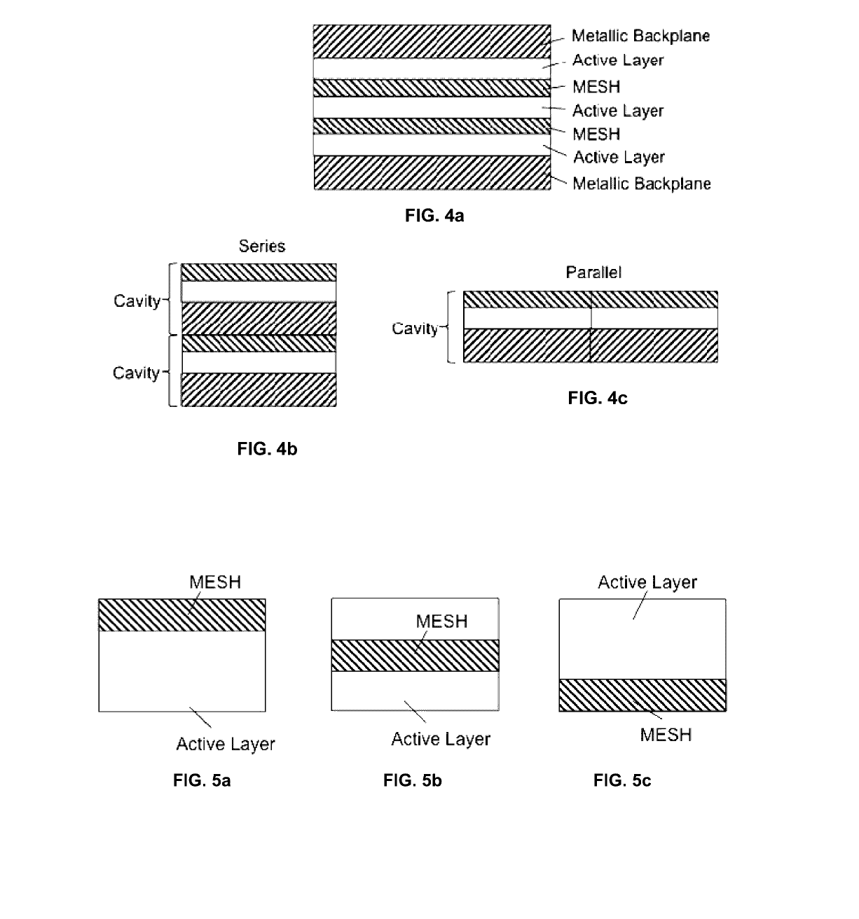

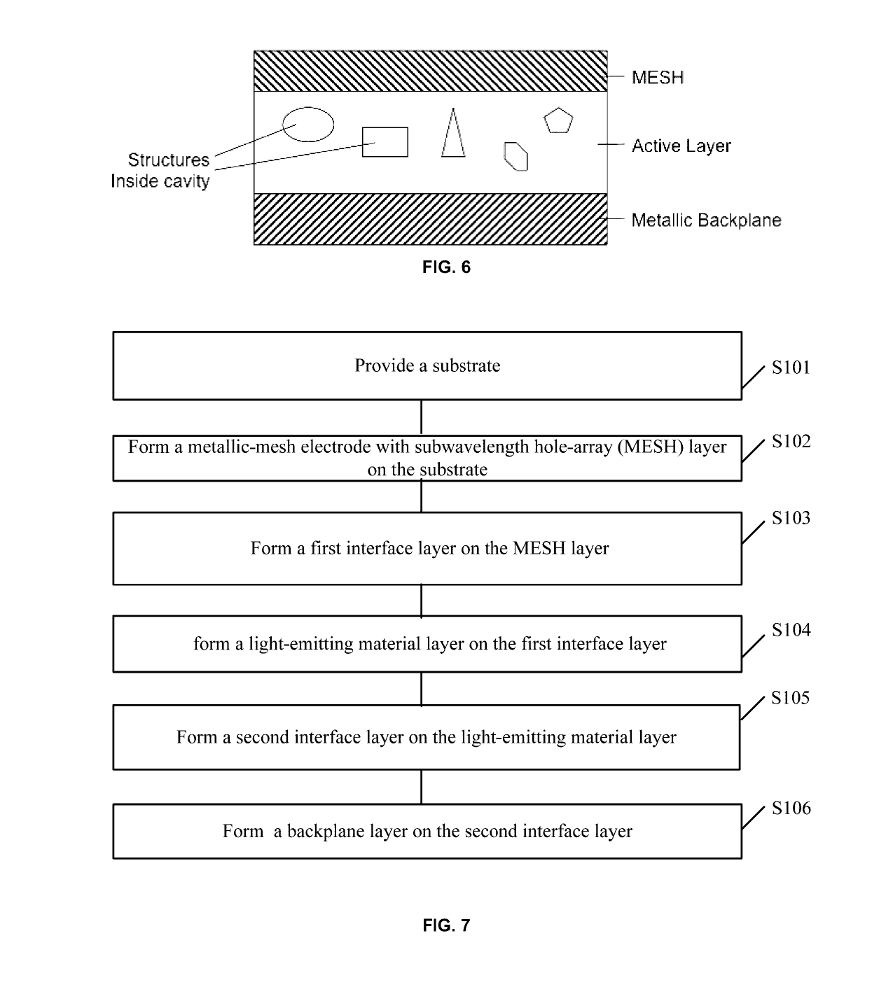

FIGS. 6A-6C depict exemplary structures of cavities in accordance with various disclosed embodiments. As shown in FIG. 4 A, a PlaCSH-LED can contain multiple metallic MESH layers that are light-transmissive, multiple backplane layers, and multiple active layers, or a combination thereof. The distances between every two adjacent layers can be the same or different, as long as most of the distances are subwavelength. As shown in FIG. 4 B, multiple identical or similar cavities can form a large cavity in series for enhanced performance or functionality. For example, three cavities respectively emitting red, blue, and green lights can be stacked in series to emit white light. As shown in FIG. 4 C, multiple identical or similar cavities, i.e., sub-cavities can form a large cavity in series for enhanced performance or functionality. For example, three sub-cavities respectively emitting red, blue, and green lights can be stacked in parallel to form a large cavity to emit white light. Sub-cavities can be integrated in a large cavity by using any appropriate fabrication techniques that are not limited by the present disclosure.

In certain embodiments, a cavity can solely include one or more MESH layers that are light-transmissive and one or more active layers. In those cases, the top metallic layer(s) and surface(s) of the active layer(s) can form one or more cavities. FIG. 5 A-7C depict exemplary structures of cavities in accordance with various disclosed embodiments. As shown in FIG. 5 A, a MESH layer can be at the top of a cavity. As shown in FIG. 5 B, a MESH layer can be sandwiched within two active layers and thus be located inside a cavity. In other words, the top metallic layer can be located inside a cavity and in between two sub-cavities. As shown in FIG. 5 C, a MESH layer can be at the bottom of a cavity.

The backplane layer can have a flat structure or can include subwavelength structures. In one embodiment, in a film deposition process for fabricating a cavity, e.g., forming MESH layer deposition followed by forming an active layer and followed by forming a backplane layer, the same subwavelength structure on the top metallic layer can be duplicated onto the metallic layer. In another embodiment, the metallic backplance layer can be directly patterned. The patterns can have any appropriate shape including a round (i.e., circle), a polygon, a triangle, a hole or a pillar with random edges, or a superposition and/or combination thereof. The holes or pillars can be periodic and aperiodic. The size and the shape of each pattern (hole or pillar) can be the same or different from other patterns, as long as substantially most of the patterns are subwavelength.

The cavity length can be optimized for certain application requirements, such as maximize/minimize absorption from outside the cavity for certain wavelength range, maximize/minimize light emission from inside the cavity for certain wavelength range, maximize/minimize viewing angle of light emission, maximize/minimize angle/polarization-independent absorption of light, maximize/minimize electron emission from inside the cavity, and the like. Thus, an optimized cavity length might not necessarily be the same and the best from a classic cavity (resonance) point of view.

FIG. 8 depicts a structure of an exemplary cavity in accordance with various disclosed embodiments. As shown in FIG. 8, the cavity can include subwavelength structures inside the active layer. The subwavelength structures can be made of one or more materials that are metallic or nonmetallic, and can have any shape including sphere, rectangle, hexagon, and/or any other polyhedron. The distribution of the subwavelength structures in the active layer can be uniform or nonuniform. The subwavelength structures can help to further enhance the performance of the cavity in various applications. For example, the subwavelength structures can include high index (e.g., silicon) nanoparticles to enhance light trapping/scattering, metallic (e.g., gold, silver) nanoparticles to enhance the light emission, and/or up/down conversion nanobeads to expand the absorption/emission spectrum range.

To further improve the contrast without a significant reduction of the external quantum efficiency of the PlaCSH-LEDs, one or both of light absorbing materials and light absorbing structures can be added. The light absorbing materials and/or structurse can be inside and/or on the surface of the light-emitting material layer 18, or on the surface or the surfaces of the top metallic layer 14 and/or the backplane layer 16. The lignt absorbing materials can have an absorption spectrum different from the LED's light emission spectrum, in order to improve contrast. The light absorption enhancement structures can include nanostructures.

The photonic resonant cavity antenna formed using the disclosed process as above can have one or more of the following characteristics:

a. improved production of light produced in the light emitting material layer 15 and produced outwardly from the light emitting diode; and

b. improved efficiency of converting a received electric current to photons that are produced outwardly from the light emitting diode; and

c. improved contrast by enhancing the ambient light trapping (broadband, independent of ambient light polarization and angle)

The metallic photonic resonant cavity antenna 12 can, for certain light wavelength range (i.e., “working band”), enhance radiation and the extraction of light from the light-emitting material 18 inside of the cavity to the free space outside of the cavity antenna as well enhance the optical pumping light (if needed) to enter the cavity 12 from outside to inside. The enhancements, the center wavelength and the bandwidth of the working band depend upon several factors, including the materials and geometry of one or some or all of the light-emitting material layer 18, the top metallic layer 14, the first interface layer 22, the second interface layer 24, and the backplane layer 16.

In various embodiments, the geometry can refer to any of the thickness of each of the above layers, size and period of the holes or disks in the top metallic layer 14. The factors of geometry can be optimized to maximize radiation to the free space in the selected radiation wavelength of a particular light-emitting material layer 18.

1. As shown in FIG. 1, the cavity structure can contain several metallic layers that is light transmissive (MESH), backplane metallic layers, active layers or any combination of them. The distances between each layers can be the same or different, as long as most of them are subwavelength. Multi same cavities can form a larger cavity in series or in parallel for enhanced performance.

2. The cavity structure can contain only metallic layers that is light transmissive (MESH) and active layers. The metallic layers can be on top, inside or on bottom of the cavity. In this cases, the metallic layers and surfaces of active layers form cavities.

3. The bottom backplane metallic layer can be flat or contain subwavelength structures. a) In the film deposition process to fabricate the cavity (MESH->active layer->metallic backplane layer), the same subwavelength structure on MESH will be duplicated onto this bottom metallic layer. b) Direct pattern on the metallic backplane layer. The patterns can have any shape including a round, a polygon, a triangle, hole/pillar with random edges or a superposition and combination of one or more thereof. The holes/pillars can be periodic and aperiodic. The size and the shape of each pattern can be the same or different from other pattern, as long as most of them are subwavelength.

4. The cavity length can be optimized for certain application requirements, such as maximize/minimize absorption from outside the cavity for certain wavelength range, maximize/minimize light emission from inside the cavity for certain wavelength range, maximize/minimize viewing angle of light emission, maximize/minimize angle/polarization independent absorption of light, maximize/minimize electron emission from inside the cavity, and others, thus might not always be the same and the best from classic cavity (resonance) point of view.

5. The cavity can contain subwavelength structures inside the active layer. The subwavelength structures can have materials of metallic or nonmetallic, can have any shape including sphere, rectangle, hexagon or any other polyhedron. The distribution in the active layer can be uniform or non-uniform. These structures can help further enhance the performance of the original cavity in various applications. Examples include enhancing the light trapping/scattering with high index (as Silicon) nanoparticles, enhancing the light emission with metallic (as Gold/Silver) nanoparicles, expanding the absorption/emission spectrum range with up/down conversion nanobeads.

The light emitting diode assembly of claim 15 wherein functional layer is a bulk heterojunction material that including a mixture of a hole material and an electron material.

The light emitting diode assembly of claim 15 wherein the functional layer has a thickness that is optimized for radiating inside of the cavity antenna to outside thereof and for ambient light trapping outside to inside of the cavity antenna.

To further improve the contrast without a significant reduction of the external quantum efficiency of the PlaCSH-LEDs is to add light absorbing materials or structures, or both. The light absorbing materials and structure can be inside and on the surface of the light emitting materials, or on the surface or the surfaces of the front or the back electrodes. The lignt absorbing materials can have an absorption spectrum different from LED's light emission spectrum to improve the contrast. The light absorption enhancement structures include nanostructures.

The light emitting diode assembly of claim 1 wherein the photonic resonant cavity antenna has one or more of the following characteristics:

a. improved production of light produced in the light emitting material layer 15 and produced outwardly from the light emitting diode; and

b. improved efficiency of converting a received electric current to photons that are produced outwardly from the light emitting diode; and

c. improved contrast by enhancing the ambient light trapping (broadband, independent of ambient light polarization and angle)

The photonic resonant cavity antenna 12 can, for certain light wavelength range (so-called “working band”), enhance radiation and the extraction of light from the light-emitting material 18 inside of the cavity to the free space outside of the cavity antenna as well enhance the optical pumping light (if needed) to enter the cavity 12 from outside to inside. The enhancements and the center wavelength and the bandwidth of the working depend upon several factors, including the materials and geometry of the light-emitting materials, the top metallic layer, the top interface layer and the bottom interface layer, and the material of the bottom metallic layer. The geometry above means the thickness of these layers and the later size and period of the holes or disks in the top metallic layers. The factors should be optimized to maximize the radiations to the free space in the selected radiation wavelength of a particular light-emitting layer 18.

For the LED 10, the disclosed embodiment is for the cavity 12 to act as an antenna to radiate the light generated inside the cavity 12 to outside, rather than strong absorption for the light coming from outside of the cavity. Therefore, the cavity 12 for the LED 10 is longer (i.e., thicker) than that for the photoelectron source 60 and the photodetector 100. A typical length of the cavity 12 for polymer light-emitting materials is from about 50 nm to about 300 nm. These parameters are critical for the enhancement and the working band. An improper design (mismatch the device working band with working wavelength) will greatly reduce the enhancement and working band.

Typically, the thickness of the light-emitting layer 18 is in the range of about 20 nm to about 300 nm. The top metallic layer 14 has a period of the hole array of about 50 nm to about 400 nm for the visible light emission, and a thickness between about 10 nm to about 80 nm. The bottom metallic layer thickness between about 50 nm to about 500 nm and average reflectance greater than about 90%.

All materials described in this disclosure can be in crystal, polycrystalline, amorphous, or hetero-mixture. The hetero-mixture means that difference material in small grains are mixed together.

The various parameters of the LED 10 can enhance the performance and the working band. An improper design may greatly reduce the enhancements and working band.

In light of the above problems and other problems, one of the aspects of the present disclosure is to provide low reflection and low glare by using a device assembly having a novel structure. The novel structure is a novel subwavelength plasmonic nanocavity, also referred to as “plasmonic cavity with subwavelength hole-array” (PlaCSH). In addition, such a device assembly can also at the same time improve light emission from a light-emitting material inside the device assembly and improve light extraction from the light emission material.

Substrates 30

The substrate 30 can be selected from one or more of thin flexible film, and thick and relative rigid substrates. The substrate 30 can be made of a material that is polymer, glass, an amorphous material, crystal, polycrystalline, granular, or a combination thereof. The thin film substrate has a thickness from 100 to 1 micron. Another range of the thin film thickness is from above 1 micron to 100 micron r. Another range of the thin film thickness is from above 100 micron to 1 millimeter. The substrate can be made of metal, semiconductors, or insulators, or a combination thereof.

All materials described in this disclosure can be in crystal, polycrystalline, amorphous, or hetero-mixture. The hetero-mixture can refer to a mixture made of different materials are mixed together as in small grains.

In some embodiments where the metals are deposited on a non-metal surface, an adhesion layer may be deposited between the non-metal surface and the metal layer. The adhesion layer includes titanium, chromium, nickel and others.

Fabrication of PlaCSH LEDs

The LED 10 can be fabricated in many different ways using a variety of technologies. The LED 10 can be fabricated on a substrate with the light emitting surface facing the substrate (light going through the substrate) or away from the substrate, or LED 10 can be peeled off from a substrate to become stand alone. The fabrication technologies comprise one, several, or all of the following technologies: lithography, etching, and deposition.

For illustrative purposes, fabrication methods for making all the devices described in this disclosure include, but are not limited to, at least one or more of the following. The deposition of materials can be performed by MBE (both regular and temperature molecule beam epitaxy), evaporation (thermal or electron beam), sputtering, chemical vapor deposition (CVD), atomic layer deposition, spinning, and casting. The patterning of nanostructures can be performed by nanoimprint, electron beam and ion beam lithography, optical lithography, self-assembly, as well as lift-off and etching. The nanoimprint can use the form of the plate to plate, the plate to roll, or the roll-to-roll. The fabrication can also involve bonding of the part of the device with other part of the device and bonding of the device to a substrate. The etching comprise of one or several of wet-chemical etching, dry etching (e.g. reactive ion etching), sputtering and ion milling.

A method for forming a light-emitting diode (LED), comprising:

forming a metallic-mesh electrode with subwavelength hole-array (MESH) layer that is transmissive to a light emitted by the LED and that has at least one lateral structure smaller than a wavelength of the light; forming a backplane layer; and forming a light-emitting material layer positioned between the top metallic layer and the backplane layer, wherein the light-emitting material layer is grown by using at least one of low temperature molecule beam epitaxy and thin film deposition.

In the method above, the forming of the top metallic layer 14 comprises transfer printing. In the transfer printing, the top metallic layer is first fabricated on a carrier substrate, and then press it against the LED substrate making the top metallic layer 14 to stick to the LED substrate and then separate the carrier substrate from the top metallic layer 14.

As an example, FIG. 5 depicts a flow diagram of a method for forming the LED 10 with for the top metallic layer 14 facing the substrate 30 (light goes through the substrate). FIGS. 2A-2F depict cross-sectional views of the LED at various stages during a fabrication process in accordance with various disclosed embodiments. Note that although FIGS. 2A-2F depict device structures corresponding to the method depicted in FIG. 1, the device structures and the method are not limited to one another in any manner.

In Step S101 of FIG. 5 and referring to FIG. 8 A, a substrate 30 is provided. A PlaCSH-LED device in various embodiments described herein can be either supported by the substrate 30 or stand on its own (i.e. self-supported). Therefore, providing of the substrate 30 is optional and can be omitted depending on specific fabrication techniques and design of device structure.

When the PlaCSH-LED is supported by a substrate 30, the substrate 30 can be used as a layer in contact with a subsequently-formed MESH layer. During the operation of a subsequently-formed PlaCSH-LED, light can transmit in and/or out of the PlaCSH-LED through the substrate.

In Step S102 of FIG. 5 and referring to FIG. 8 B, a metallic-mesh electrode with subwavelength hole-array (MESH) layer 14 is formed. In one embodiment, when the substrate is provided as described in Step S101, the PlaCSH-LED can be fabricated face-down, and the top metallic layer can be formed on the substrate. In another embodiment, when the substrate is provided as described in Step S101, the top metallic layer 14 can be formed on a carrier and transferred to the substrate in certain subsequent processes. Any appropriate transfer or lamination techniques can be used, including, e.g., microncontact printing, or/and the like. The carrier can include any appropriate substrate-type layer that meets fabrication requirements or product applications. In yet another embodiment, when the substrate is not provided as described in Step S101, the top metallic layer 14 can be formed on a carrier.

FIGS. 3A-3D depict structures of an exemplary MESH layer in accordance with various disclosed embodiments. FIG. 3 A depicts a 3-D perspective view of a structure of an exemplary MESH layer in accordance with various disclosed embodiments. FIG. 3 B depicts a top view of the structure in FIG. 3 A. FIG. 3 C depicts a 3-D perspective view of a structure of an exemplary MESH layer in accordance with various disclosed embodiments. FIG. 3 D depicts a top view of the structure in FIG. 3 C.

As shown in FIGS. 3 A and 3B, the top metallic layer 14 can include a metallic material layer 60. The metallic material layer 60 can include a thin metallic material film 62 having an array of holes (or apertures) 64. A distance between two adjacent holes and a size of each of the holes can be less than a wavelength of photons (i.e., light) emitted by the subsequently-formed LED. When optical pumping is used for the LED, the distance between two adjacent holes and the size of each of the holes can be less than a wavelength of the pumping photons.

As shown in FIGS. 3C-3D, the top metallic layer 14 also can include an metallic material disk array 40.

In Step S103 of FIG. 5 and referring to FIG. 8 C, a first interface layer 22 can be formed on the top metallic layer 14. The first interface layer 22 is optional and can be omitted.

In Step S104 of FIG. 5 and referring to FIG. 8 D, a light-emitting material layer 18 is formed on the top metallic layer 14. When the first interface layer 22 is previously formed, the light-emitting material layer 18 can be formed on the first interface layer 22. The light-emitting material layer 18 can be used for emitting photons when an electric current flows through or when incoming photons irradiates upon the subsequently-formed LED. In various embodiments, the light-emitting material layer 18 can also be referred to as a functional layer 18, or an active layer 18.

In Step S105 of FIG. 5 and referring to FIG. 8 E, a second interface layer 24 can be formed on the light-emitting material layer 18. The second interface layer 24 is optional and can be omitted. The second interface layer 24 can be used for providing good adhesion between layers. That is, the second interface layer 24 can serve as adhesion layer. The second interface layer 24 can further block and/or transport a particular electrical charge carrier type (serving as charge carrier blocking/transporting layer), or enhance the performance of the cavity antenna (serving as a spacer). The spacer might be needed in a metallic photonic cavity to reduce certain quenching of light by metal.

In Step S106 of FIG. 5 and referring to FIG. 8 F, a backplane layer 16 is formed on the light-emitting material layer 18. When the second interface layer 24 is previously formed, the backplane layer 16 can be formed on the second interface layer 24.

Applications

The LED 10 can be used in many areas in illumination and visualizations (by human or other living species), which can be categorized as, but not limited to, (1) visual signals where light goes more or less directly from the source to the human (or other living species) eye, to convey a message or meaning; (2) illumination where light is reflected from objects to give visual response of these objects; (3) sensing, measuring, and photo-assisted processes (physical, chemical, biological processes for examples); and (4) being used as photodetectors rather than LED (i.e. light sensors) where LEDs operate in a reverse-bias mode and respond to incident light, instead of emitting light.

Examples of application for displays, but not limited to, are (1) hand held or wrest-watch-type electronics (smartphones, etc.); (2) TVs, (3) Sports Stadium LED Display (Scrolling LED Display Monitor. The sports stadium LED display is used to display pictures and videos when there is a sports event or a recreational activity held at a stadium); (3) Advertising LED Display Board; (4) Wall size LED Display; and (5) Other display application as: Stage LED Display Screen; Giant LED Display; Airport LED Display, and (6) Other applications are (a) Flashing. PlaCSH-LED can be used as attention seeking indicators without requiring external electronics; and (b) Indicators and signs.

Another important application of LED 10 is for the use of the same device as both display and photon imager (camera), particularly, when they are made in matrix from (rows and columns of LED 10).

Examples of application for lighting, but not limited to, are: Lighting in retail. The PlaCSH-LEDs are suited to retail outlets. They can provide a wide range of effects that contribute to the total shopping experience and allow people to set the right scene for every occasion. LED solutions can highlight a product, create drama and interest, but can also reflect mood, helping create the perfect environment for the shopping experience. Lighting in offices. PlaCSH-LED lighting offers great support for: freedom of shape and design, use of colors, dynamic effects in intensity and direction, and creating spaces for enhanced people comfort and wellbeing. On top of this, LED brings great energy saving, especially when combined with lighting controls. Lighting in hospitality. The Hospitality industry is one of the sectors with the largest energy savings potential. PlaCSH-LED technology holds tremendous potential to conserve energy on a global scale. LED lamps set new standards in watts consumed per square meter, especially combined with lighting controls. Lighting outdoor spaces. PlaCSH-LEDs provide an unparalleled way of illuminating our urban environment in an exciting and practical manner. They are highly adaptable, allowing designers to move away from the static lighting of the past and venture into creating flexible ambiances that could, for example, change with the weather or the season, and provide an extra festive color on public holidays. And all this with energy consumption that is only a fraction of conventional lighting techniques. Lighting in healthcare. People who have to stay in the hospital often feel anxious, and many times not at ease. This could make examination processes more difficult and time consuming PlaCSH-LED lighting can create more colorful and soft ambiences that makes the environment seem less clinical and more human, which is beneficial for both how people feel and for the quality and speed of the diagnosis process. In addition to this, PlaCSH-LED lighting offers a significant energy saving potential, especially for corridors and general spaces in the hospital. PlaCSH-LED lighting can change the atmosphere in diagnosis areas and patient rooms, improving the hospital life for both patients and staff. The energy saving potential is great, reducing the operational cost of the hospital. Lighting in industry. Huge industrial sites with their vast size and 24/7 operations surely consume an equally huge amount of energy for lighting. And the super high ceilings make maintenance or lamp replacement very costly as well—especially, if the processes need to stop for the maintenance. PlaCSH-LED solutions can help people overcome these challenges. PlaCSH-LED solutions are designed to significantly reduce the energy consumption without compromising the light level and greatly extend the lifetime, eliminating frequent lamp replacement. Sterilization (for sterilizing microbiological contaminants from irradiated surfaces). Therapy (for the treatment of skin conditions such as psoriasis and vitiligo). Application in Agriculture and Horticultural Industry.

Another 15 examples of LED lighting in application are the following. #1. Freezer Case (LED lighting produces a compound energy benefit when installed in freezer cases. Substantial energy savings can result from the improved directionality of LEDs, better optical control, less light loss from operation of fluorescent lamps at low temperature, and reduced heat.) #2 Infrastructure Effect Lighting (The use of color LEDs produces a dramatic effect on water, as well as the otherwise stark grey concrete of large structures. #3. General Lighting with Conventional Control (Retrofit downlighting connected to a compatible dimmer produces the combined efficiency of LEDs with the simplicity of conventional lighting). #4. Colorful Residential Lighting (The use of color was initially considered as a novelty but is now possible as an exciting home feature. In this residence, color is controlled using a DMX interface through wall station control activation of preset programmed effects. Programming is managed through wall controls or PC connection to the main control panel.) #5. Facade Branding and Display Effects (white LEDs illuminate the structure behind a metal screen that wrapped the building. Theatrical controls and DMX protocols were used to create dynamic graphics and fixed lighting effects, programmed by store display specialists using computer software that provides a graphic representation of the building that is painted with light. Daylight sensing changes functions, or turns the system off) #6. Theatrical House Side Lighting (LED lighting was selected for the cove and balcony rail lighting effects. These were controlled with other house lighting used on the walls and in the ceiling using the same controls as would be used in any performing arts center of this scale.) #7. Daylight Control (The LED light panels diffuse daylight and add fill. Daylight controls as well as standard large-area building controls were employed. Control of the LED fixtures was integrated with control of conventional lighting products used in other areas through a large centralized dimming and programmable control system.) #8. Integrated Display and General Illumination Effects (In this application, LEDs were used to create shades of white, as well as a moving artistic message on the wall. Control is through DMX interface, while programming of the effects is accomplished using a standard PC and third-party graphic software.) #9. Special Effects (Public spaces are transformed by color, or moving light effects, using easy to program software and interactive controls. This allows public space to be continuously changing, and responsive to seasons and special events.) #10. Outdoor Facade Lighting (White light applications of LEDs are controlled in the same manner as any other lighting product, and outdoor applications such as this one are no exception.) In outdoor applications, time-clock and photosensor controls, combined with standard relay contactors, can be employed in the same manner as any conventional source. #11. Facade Textured Effects (The use of exposed LED sources and DMX controls through PC software provides static and dynamic lighting patterns in an infinite array using white light sources.) #12. Workstation Lighting (Fluorescent lamps do not instantly achieve full brightness after ignition, and suffer shorter life when there is frequent switching. LED lighting provides instant-on response and does not suffer any negative effects from frequent switching—compounding their already superior optical performance advantage in task lighting applications.) #13. Commercial Interiors (In this application, 100% of the lighting is LED, controlled by a combination of conventional line-voltage load controls, using typical wall stations and daylight sensors to reduce electric lighting when not needed.) #14. Video Effects (The use of LEDs in large video quality systems crosses the lines between lighting, entertainment and signage. An application such as this would be impossible using conventional lamp and control technology.) #15. White Light Tuning (Control of color or white light blending using either DMX or proprietary controls with wall station activation of preset scenes offers new lighting opportunities, without the inefficiencies of conventional dimming on incandescent lamps, or the light losses experienced with color filters used over incandescent or fluorescent lamps.)

### Example

Aspects of the present teachings can be further understood in light of the following examples, which should not be construed as limiting the scope of the present teachings in any way.

In one non-limiting example, a PlaCSH-OLED can have a novel subwavelength plasmonic nanocavity, PlaCSH. The PlaCSH can include two cladding layers. A first cladding layer of the two cladding layers can be a light-transmissive metallic-mesh electrode (i.e., a MESH layer). The top metallic layer can have a subwavelength hole-array. A second cladding layer of the two cladding layers can be a metallic back electrode (i.e., a backplane layer). The backplane layer can be opaque and planar. The two cladding layers can have light emitting materials (i.e., a light-emitting material layer) therebetween.

In an optimized above PlaCSH-OLEDs fabricated, the top metallic layer can include a 15-nm-thick Au mesh. The Au mesh can have a hole array. The hole array can have a period of about 200 nm, and a hole diameter of about 180 nm. An AuOₓ atomic layer can be formed on the surface of the Au mesh. The backplane layer can include an Al film having a thickness of about 100 nm. An LiF layer having a thickness of about 0.3 nm can be formed on the backplane layer as a second interface layer.

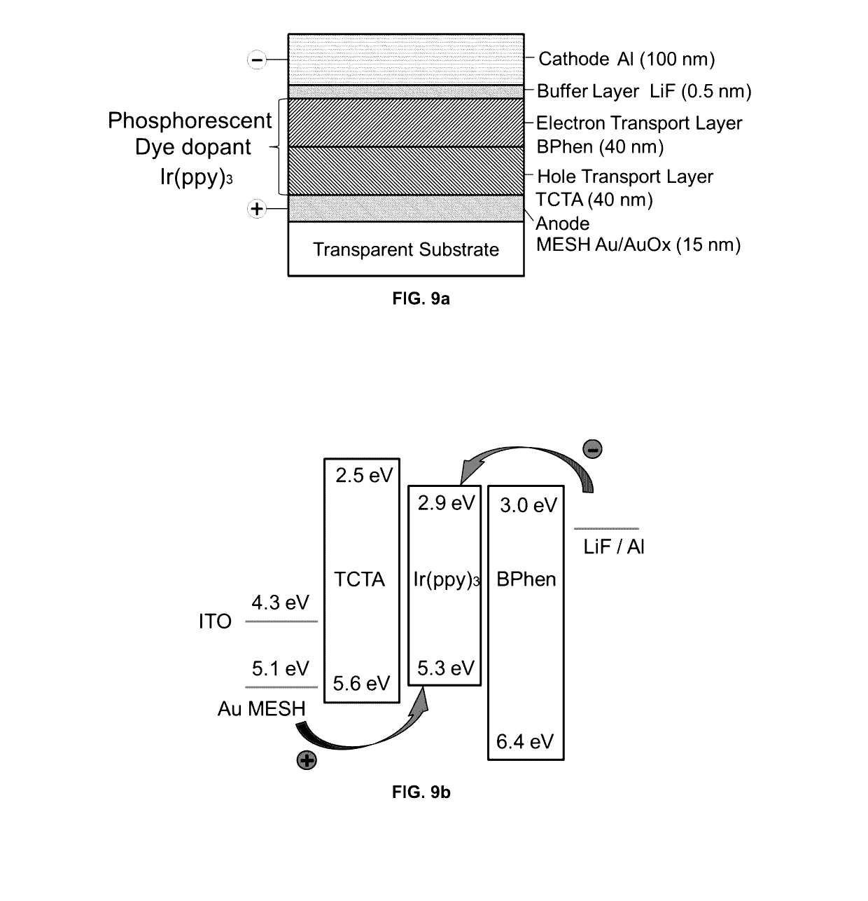

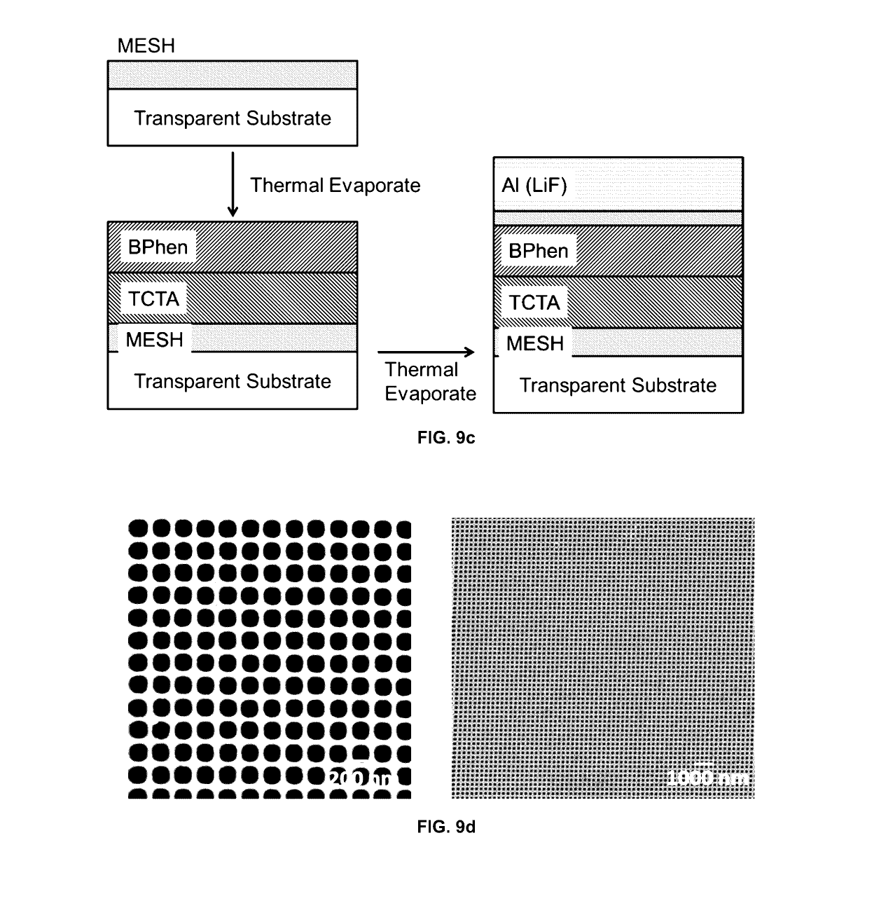

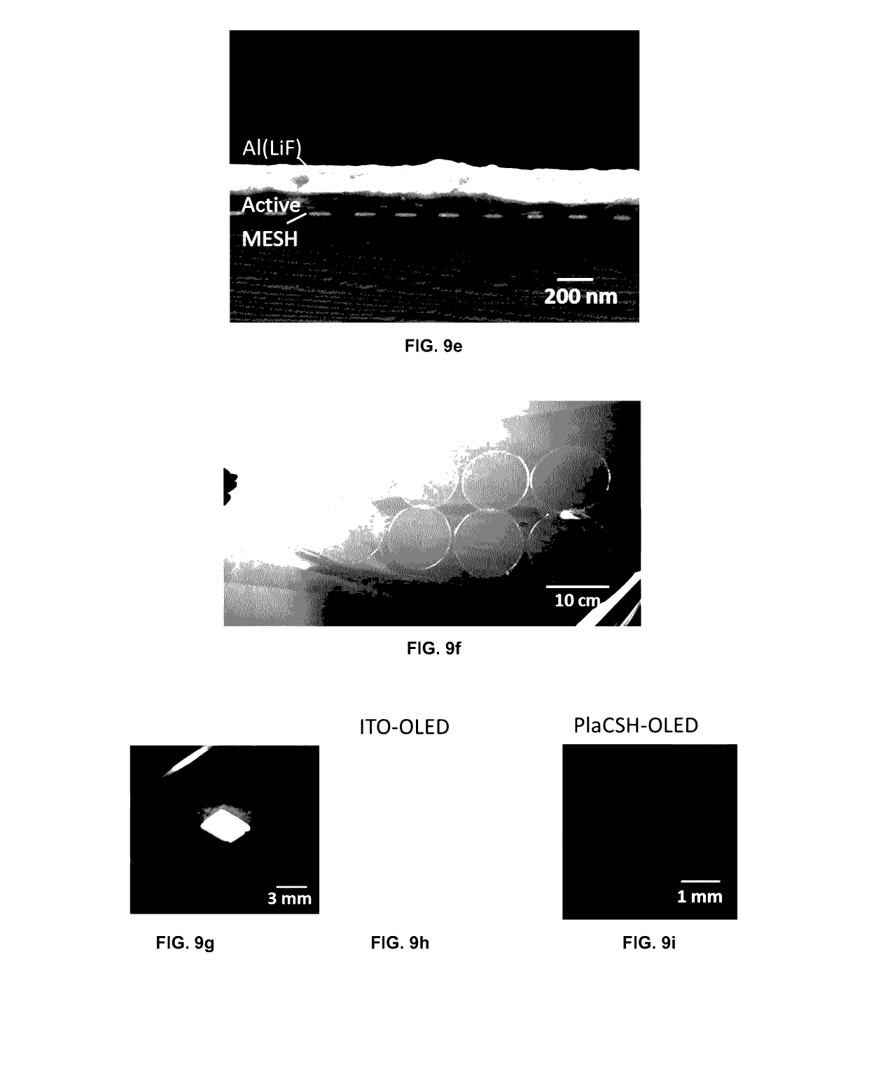

The light emitting-material layer can include a hole transporting material layer. The hole transporting material layer can be made of green phosphorescent host-guest materials of 4,4′,4″-tris(carbazol-9-yl) triphenylamine (TCTA). The light emitting-material layer can further include an electron transporting material layer made of 4,7-diphenyl-1,10-phenanthroline (BPhen. The light emitting-material layer can have a total thickness of about 80 nm. Both of the hole transporting material layer and the electron transporting material layer can be uniformly doped with a phosphorescent guest, fac-tris(2-phenylpyridine) iridium(III) [Ir(ppy)3] (Referring to FIG. 9A as below). The PlaCSH-OLED can have a total thickness without a substrate is 195 nm. The PlaCSH-OLED can be formed on a substrates made of fused-silica having an index of about 1.46.

With the phosphorescent guest Ir(ppy)3, both the singlet and triplet states can be used for light emitting. Thus, the internal quantum efficiency can be high and estimated to be about 92% for certain devices as disclosed herein. The light emitting material layer can have a luminescence peak at about 520 nm and an index ranging from about 1.65 to about 1.70. The substrate used can be made of fused-silica having an index of about 1.46. The top metallic layer can have a period of about 200 nm, which can be less than the peak wavelength in the light emission material/n=306 nm), and can match well with surface plasmon wavelength in the plasmonic cavity antenna.

According to an over-simplified model λ=λ_0/√(∈_m ∈_a/(∈_m+∈_a)), λ can be about 200 nm for λ_0=520 nm light at the interface between Au mesh and the active layer. ∈_m and ∈_a refer to permittivity at the interface between the Au mesh and the active layer.

To reduce non-radiative loss (e.g. Joule loss) in the top metallic layer, both the thickness of the top metallic layer and width (any of width of a hole in the hole array, distance between adjacent holes, width of a disk in the disk array, and distance between adjacent disks) can be kept in deep subwavelength size (e.g., 15 nm and 20 nm. respectively). A good lateral DC electrical conductivity can still be maintained. Many of the rules and specific parameters in designing the PlaCSH-OLED are based previous experiments in PlaCSH-photovoltaic devices and related plasmonic nanostructures.

In PlaCSH-OLED operation, holes and electrons are supplied by the top metallic layer and the Al backplane layer, respectively. The holes and electrons can then be recombined in the light-emitting material layer to generate photons (light). With phosphorescent guest Ir(ppy)3, both the singlet and triplet states can be used for light emitting, thus the intrinsic quantum efficiency can be high and estimated to be about 92%.

The key functions of the plasmonic nanocavity, PlaCSH, can include, as shown later, (a) drastically enhancing the effective light extraction to outside over broadband and hence EQE; (b) significantly increasing the absorption of the ambient light over a broad bandwidth and all incident angles and polarizations, hence leading to a significant enhancement of the contrast and low-glare; and (c) controlling the far-field radiation patterns, hence enhancing the viewing angles and brightness.

FIG. 9A depicts an exploded view of an exemplary PlaCSH-OLED in accordance with various disclosed embodiments. FIG. 9B depicts an energy band diagram of the PlaCSH-OLED depicted in FIG. 9A in accordance with various disclosed embodiments. FIG. 5C depicts an exemplary fabrication process of the PlaCSH-OLED depicted in FIG. 5A in accordance with various disclosed embodiments.

In the example as shown in FIG. 9C, PlaCSH-OLEDs were fabricated on a 4″ fused silica substrate (about 0.5 mm thick) using planar or roll nanoimprint lithography (NIL). The 4″ NIL molds having a mesh pattern of 200 nm period and different hole sizes over the entire mold were fabricated using a combination of interference lithography and then multiple NIL, etching, and self-perfection.

FIG. 9F depicts an exemplary large area roll-to-roll flexible mold for a MESH layer in accordance with various disclosed embodiments. As shown in FIG. 9F, large-area flexible roll-to-roll molds (50 cm×20 cm) for the MSEH were fabricated.

The MESH on fused silica was fabricated by NIL and the deposition and lift-off of 15 nm thick Au, followed by a UV-ozone treatment (15 min) to form an atomic thick AuOx on top. Then the layers of 35 nm thick TCTA and 45 nm thick BPhen (both are 2 wt % Ir(ppy)3 doped. All materials are commercial products from Sigma Aldrich, used as received) were sequentially evaporated thermally onto the MESH under ˜10⁻⁷ torr without breaking vacuum. Finally, the LiF (0.5 nm) and Al (100 nm) film were evaporated through a shadow-mask, which defines the back electrode and hence the OLED active area, that is typically 3 mm by 3 mm.

FIG. 9D depicts a scanning electron microscopy (SEM) image of an exemplary MESH layer in accordance with various disclosed embodiments. As shown in FIG. 9D, the top metallic layer has a 200 nm pitch, 180 nm hole diameter, a hole shape close to square with round corners and smooth edges, and has excellent nanopattern uniform over large area. FIG. 5E depicts a cross-sectional SEM image of an exemplary PlaCSH-OLED in accordance with various disclosed embodiments. As shown in FIG. 9E, the organic films covering nanoscale MESHs without any observable pin-holes. Further, FIG. 9G depicts green light emission from an exemplary PlaCSH-OLED in accordance with various disclosed embodiments.

In an example disclosed as follows, a PlaCSH-OLED as shown in FIG. 9 was fabricated according to the method as disclosed in various embodiments above. For comparisons, two types of reference LEDs were fabricated. The reference LEDs include an “ITO-OLED” and a “DMD-OLED”. The “ITO-OLED” and the “DMD-OLED are substantially the same as the PlaCSH-OLED except for the top metallic layer. In the ITO-OLED, the top metallic layer was replaced by ITO (100 nm thick with 10 ohm/sq sheet resistance). In the DMD-OLED, the top metallic layer was replaced by a dielectric-metal-dielectric (DMD) electrode (Ta₂O₅ (70 nm)/Au (18 nm)/MoO₃ (1 nm)).

FIG. 9H depicts ambient light reflection of a reference ITO-OLED. As shown in FIG. 9H, ambient light reflection of reference ITO-OLED has a white color. FIG. 9l depicts ambient light reflection of an exemplary PlaCSH-OLED in accordance with various disclosed embodiments. As shown in FIG. 9H, ambient light reflection of a PlaCSH-OLED has a dark blue color. Thus, ambient light reflection of a PlaCSH-OLED can be much lower than the reference ITO-OLED.

The LEDs fabricated in the above example shows the following characteristics.

Electroluminescence and Broadband, Omni Enhancement

The spectra of the front-surface total electroluminescence of both PlaCSH and ITO-OLEDs were measured as a function of bias (injection current) using an integrated sphere (Labsphere LMS-100) and a spectrometer (Horiba Jobin Yvon), and were calibrated using a lump standard (Labsphere AUX-100). During the measurements, the backside and the four edges of all the LEDs were fully covered with black-tapes to ensure the light emission only from the LEDs' front surface.

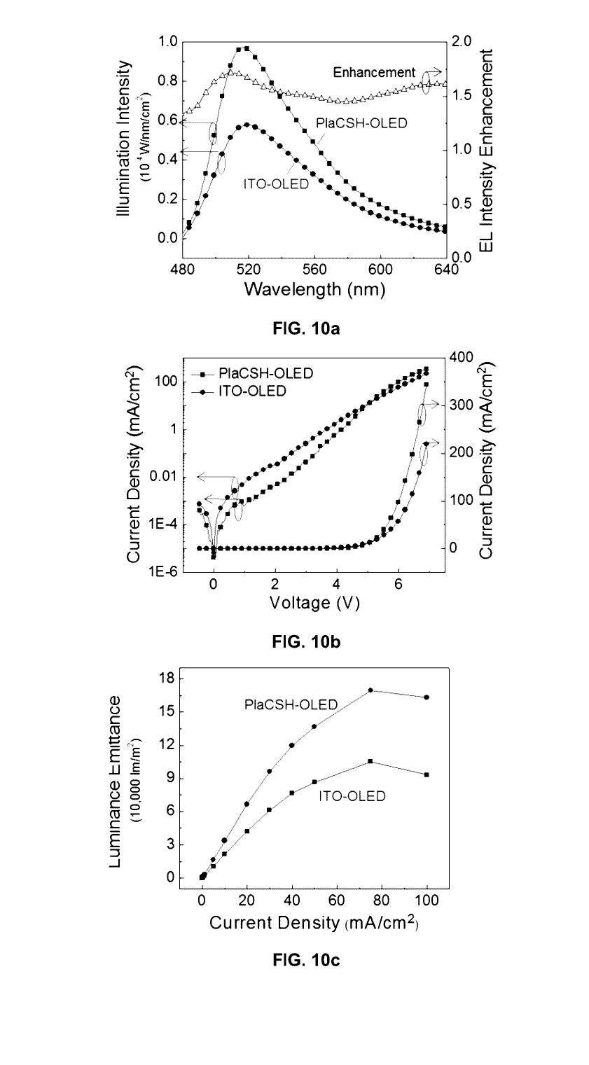

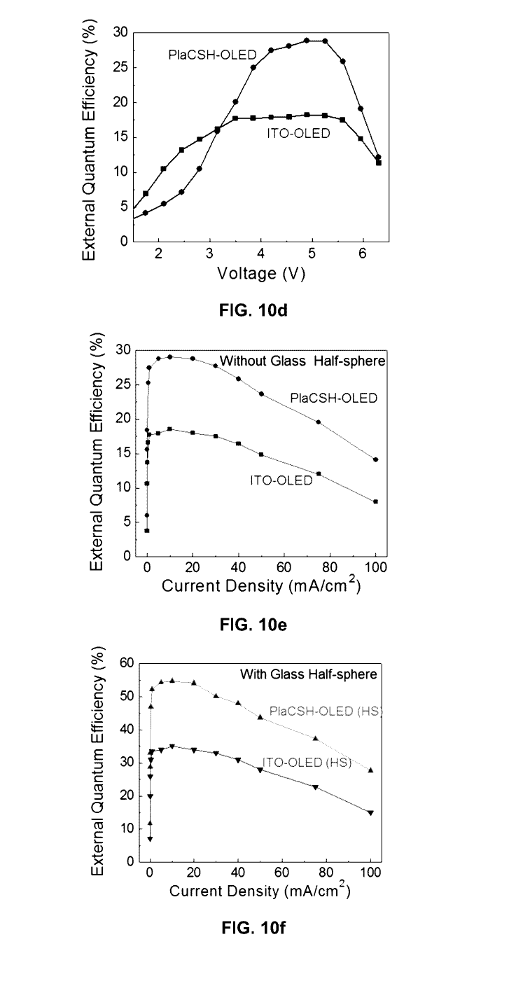

FIG. 10 depicts measured electro-luminance (EL), J-V, Luminous Emittance and EQE of PlaCSH-LEDs and ITO-LEDs. FIG. 10a depicts total front-surface EL/enhancement spectrum at 10 mA/cm2 current density. FIG. 10b depicts current density vs. voltage (J-V). FIG. 9c depicts luminous emittance vs. current density. FIG. 10d depicts EQE vs. voltage. FIG. 10e depicts EQE vs. current density without glass half-sphere. FIG. 10f depicts EQE vs. current density glass half-sphere. Compared to ITO-LEDs, PlaCSH-LEDs has an EL peak of 1.69 fold higher and 3 nm blue shift, and an EQE (at 10 mA/cm²) of 29.1% and 54.5% for without and with the glass half-sphere, both are 1.57 fold higher than ITO-OLEDs (18.5% and 35%).

The measured spectra show that the front-surface total electroluminescence (EL) intensity of PlaCSH-OLEDs is much higher than ITO-OLEDs over the entire measured wavelength range (480 nm to 640 nm). For example, at 10 mA/cm² current density, the PlaCSH-OLED's EL has the maximum of 1×10⁻⁴ W/nm-cm² at 517 nm wavelength and a total of 6.7×10⁻³ W/cm² integrated over the entire measured spectrum, which is 1.69 and 1.57 fold higher than ITO-OLEDs (0.6×10⁻⁴ W/nm-cm² and 4.3×10−3 W/cm²), respectively (referring to FIG. 10a-10f).

The measurements also show that the EL enhancement by PlaCSH (i.e. the ratio of the spectrum of PlaCSH to ITO OLEDs) is broadband: nearly constant (within +/−8%) over the entire 160 nm measured wavelength range. However, the actual PlaCSH's enhancement bandwidth should be much wider, since the EL measurement is limited by the bandwidth of the emission material. A linear superposition analysis would easily prove that the near constant enhancement over a broad wavelength band means that the radiation enhancement is nearly independent of the wavelength, radiation angle, and polarization of the original radiation inside the PlaCSH, namely “omni radiation enhancement”.

The PlaCSH-OLED's EL spectrum has a peak at 517 nm, which is about 3 nm blue shifted from ITO-OLED (520 nm peak), and a bandwidth of about 61 nm, which is 7 nm (10%) narrower than ITO-OLED (68 nm). The slight blue shift and slight narrower bandwidth can be attributed to the slight variation in the EL enhancement spectra of PlaCSH at the light emitting wavelength range.

Current Density-Voltage Characteristics and Luminous Emittance Enhancement

The current density vs. voltage (J-V) characteristics were also measured (referring to FIG. 10b). Compared to ITO-OLEDs, the PlaCSH-OLEDs, although having a similar turn-on voltage of 2.4 V @10 cd/m2 (versus 2.3 V for ITO-OLEDs), have (i) much larger current increasing slope (i.e. larger differential conductance) and hence a larger current above the threshold (e.g. 70% larger at 6V); and (ii) a smaller leakage current in both forward and reverse bias (e.g. 10 fold smaller at +2V and 1.8 fold smaller for −0.5V), which are also smaller than the OLED for the same material system reported previously.

The high current in PlaCSH-OLEDs can be attributed to hole-injection-barrier height lowering by the AuOx electrode layer over an ITO layer. The less leakage current in the PlaCSH-OLEDs than the ITO-OLEDs can be attributed to less pinholes in the organic material layers that cover the MESH (as indicated in SEM images).

Using the measured EL spectra-vs-bias and J-V, results were obtained for the light luminous emittance vs. the injection current (L-J) or the bias (L-V), by integrating the EL spectra for a given current or bias with the eye's luminosity function as the weight and dividing the device area (FIGS. 9c-9d). The L-J shows that PlaCSH-OLEDs have much higher luminous emittance than ITO-OLED, reaching 34,000 lux (=lm/m2) at 10 mA/cm2 and a maximum of 170,000 lux at 75 mA/cm2, which is 1.56 and 1.62 fold higher than that for ITO-OLEDs (22,000 lux and 105,000 lux).

External Quantum Efficiency and Power Efficiency Enhancement

The front-surface external quantum efficiency (EQEs) as a function of bias voltage or injection current were obtained from the measured EL spectra-vs-bias and J-V (referring to FIGS. 9e-9f). At the injection current range from 1 mA/cm2 to 100 mA/cm2, the PlaCSH-OLED has an EQE of a maximum of 29.1% (at 10 mA/cm2 (4.8 V)), which is 1.57 fold higher, and an average of 25%, which is 1.6 fold higher than ITO-OLED (a max EQE of 18.5% and an average of 15.6%). The enhancement in EQE by PlaCSH is the same as that in EL, indicating again that the enhancement by PlaCSH is broadband and nearly independent of wavelength and polarization over the EL spectrum. The EQE is, to our best knowledge, the highest for the OLEDs on 1.46 index glass substrate without a lens and for any substrates when the index is scaled.

To release the light trapped in the planar fused-silica substrate, an uncoated half-sphere (HS) (B270 glass of 1.51 index which is slightly higher than the substrate) was placed on the substrate surface opposite to the LEDs with a thin matching liquid layer (an index identical to the substrate) in between. The HS has a 10 cm diameter, much larger than the LED's size (3 mm), and the LEDs were placed at the HS's focal point. With the HS, the measured maximum EQE is increased to 54.5% from 29.1% for PlaCSH-OLED, and 35% from 18.5% for ITO-OLED. The increase is 1.87 and 1.89 fold for each type of LEDs, respectively, which is essentially the same (referring to FIGS. 9a-9f and Table 1). The measured EQE can be further increased by having a higher internal quantum efficiency and better index matching between the HS and the substrate (e.g. the current EQE for PlaCSH-OLEDs can become 84% for 100% IQE and a perfect index matching).

The maximum wall-plug power efficiency is 80/150 lm/W for PlaCSH-OLEDs without/with a lens, which is about 1.43 fold higher than ITO-OLEDs (56/106 lm/W). The power efficiency can be significantly increased by, in addition to increasing EQE, lowering turn-on voltage.

TABLE 1
Radiation Properties of PlaCSH-OLED and ITO-OLED

| | | | Maximum | Normal | | | | Light Extraction | |
|---|---|---|---|---|---|---|---|---|---|
| | | EQE* | Power | Direction | Viewing | Central | | Efficiency (LEE) | |
| | EQE* | (with HS) | Efficiency | Brightness* | Angle | Wavelength | Bandwidth | without HS | with HS |
| | [%] | [%] | [lm/W] | [cd/m²] | [°] | [mn] | [mn] | [%] | [%] |
| ITO-OLED | 18.5 | 35.0 | 107 | 7300 | 118 | 520 | 68 | 20 | 38 |
| PlaCSH- | 29.1 | 54.5 | 150 | 13000 | 100 | 517 | 61 | 32 | 60 |
| OLED | | | | | | | | | |
| Enhancement | 57 | 56 | 40 | 78 | — | — | — | 57 | 56 |
| (%) | | | | | | | | | |

*Under current density of 10 mA/cm².

Internal Quantum Efficiency and Light Extraction Efficiency Enhancement

For the ITO-OLEDs, light extraction efficiency (ηextr), obtained from the well-tested ray-optics model, is 20%. Thus internal quantum efficiency (IQE) for the ITO-OLEDs can be 92%, since the measured EQE is 18.5% and IQE=EQE/ηextr.

For PlaCSH-OLEDs, the Purcell effect in light radiation enhancement should be small, because the IQE without PlaCSH is already 92%. The Purcell effect was lumped into the ηextr in the equation of IQE=EQE/ηextr. Based on the measured EQEs and the estimated IQE, the effective light extraction efficiency of PlaCSH-OLEDs is 32% and 60%, respectively without and with HS. Such effective light extraction efficiencies are 1.57 fold higher than ITO-OLED (20% and 38%), and are the highest of light extraction reported for index 1.46 glass substrate and any substrate when the index is scaled. If an index perfectly matched and lossless lens is used, the estimated light extraction efficiency for the ITO-OLED and PlaCSH-OLED on 1.46 index substrate may be increased to 54% and 84%. Furthermore, if a 1.58 index substrate is used, the estimated light extraction of PlaCSH can be 42% and close to 100% without and with an index matched lens (as shown in Table. 2).

TABLE 2
Contrast of PlaCSH-OLED and ITO-OLED

| | Luminous | Contrast Ratio (CR) | | |
|---|---|---|---|---|
| | Reflectance | Ambient | Ambient | Ambient |
| | (normal | Luminance | Luminance | Luminance |
| Structure | direction) | 140 lux | 1000 lux | 10000 lux |
| ITO- | 0.67 | 490^{a)}/2,300^{b)} | 69^{a)}/330^{b)} | 8^{a)}/34^{b)} |
| OLED | | | | |
| PlaCSH- | 0.25 | 2,300^{a)}/12,000^{b)} | 330^{a)}/1,600^{b)} | 33^{a)}/160^{b)} |
| OLED | | | | |

^{a)}Under current density of 10 mA/cm².
^{b)}Under current density of 75 mA/cm².

Angular Dependence of EL, Spectra and Luminance (Brightness)

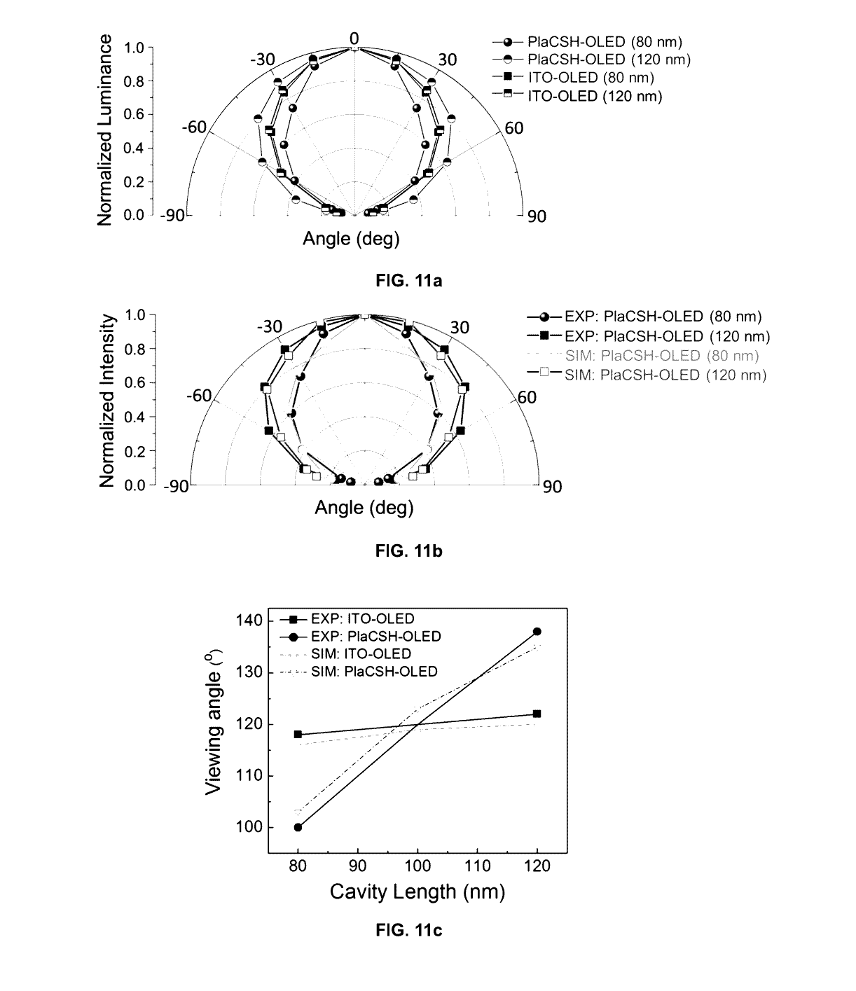

The angular dependences of EL spectra of all LED types were measured using a rotation stage, a collimation lens and a photodetector. The lens with 5 mm diameter was 5 cm away from the LEDs, thus having a 0.008 sr acceptance angle. By integrating the EL spectra over the wavelength with the luminosity function as the weight and dividing it by the acceptance solid angle and the device area, the luminance vs. emission angle was obtained (FIGS. 10a-10c, and 11a-11e).

FIGS. 10a-10c depict angular distribution of electro-luminance (EL) of PlaCSH-OLED and ITO-OLEDs in accordance with various disclosed embodiments. FIG. 11a depicts normalized luminance vs. angle. FIG. 11b depicts comparison of measurements with FDTD simulations. FIG. 11c depicts measured and simulated viewing angle vs. cavity length. Experiments show that when the cavity length is changed from 80 to 120 nm, the viewing angle is virtually fixed (120°) for ITO-OLED, but for PlaCSH-OLEDs it is changed drastically from 100° to 138° with about 1°/nm tunability (viewing angle/cavity length change). The simulations fit experiments within 5%.

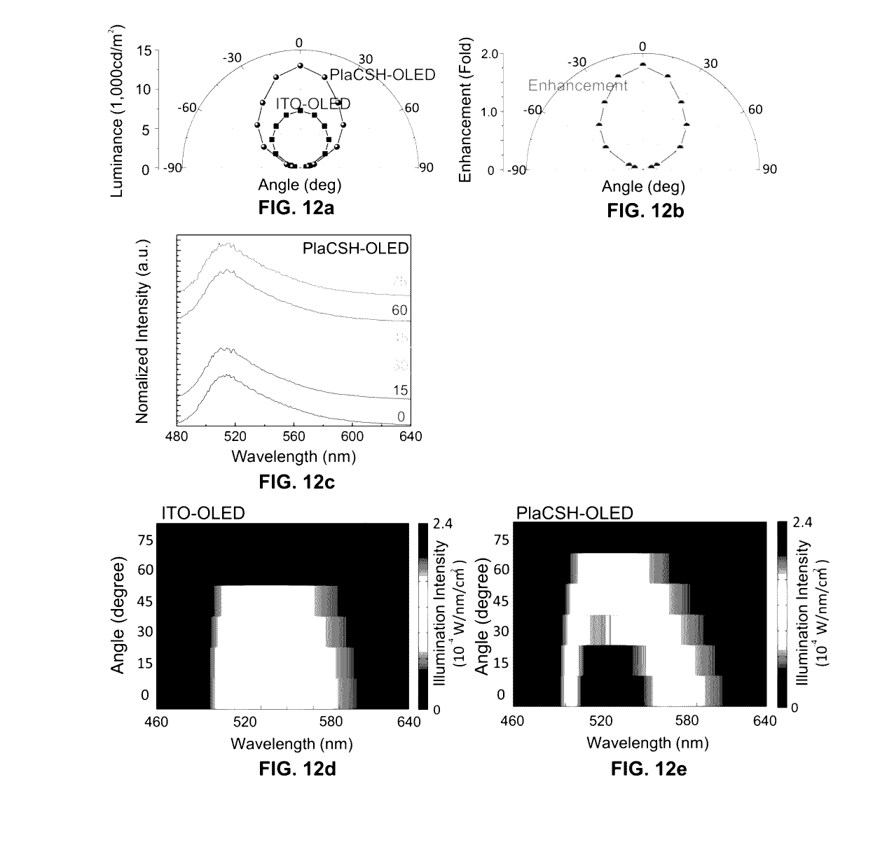

FIGS. 12a-12e depict measured angular distribution of electro-luminance (EL) of PlaCSH-OLED and ITO-OLED with 80 nm cavity length at 10 mA/cm² current density. FIG. 12a depicts Luminance vs. angle. FIG. 12b depicts Luminance enhancement of PlaCSH-OLED over ITO-OLED vs. angle. FIG. 12c depicts normalized EL spectra of PlaCSH-OLED at different angles; and (d) EL spectra vs. angle and wavelength. Experiments show that PlaCSH-OLED (with 29.1% EQE) has (i) luminance at normal direction 78% higher than ITO-OLED, (ii) EL spectra independent of angle (i.e. uniform color over angle), and (iii) 100° viewing angle—17% narrower than ITO-OLED's of the same cavity length (120°). The viewing angle narrowing channels more light to the eyes of a handheld device viewer.

First, in the ITO-LEDs, the luminance angle distribution is nearly independent of the cavity length and has a viewing angle fixed at ˜120o, as expected, since the conventional LED's emission angle distribution is always close to the Lambertian. But for PlaCSH-OLED, the angle distribution and hence the viewing angle, strongly depend on the cavity length: it can be either narrower or wider than the Lambertian (FIGS. 10a-10c). Specifically, using 80 and 120 nm cavity length, the PlaCSH-OLED's viewing angle is 100° and 138°, respectively, about 17% narrower and wider than the ITO-OLED's of the same cavity length, giving a total viewing angle tunability of 38°. while the ITO-OLED viewing angle is 118° and 122°, only having 4° tunability. The viewing angle tunability per cavity length change in the current PlaCSH-LED is 1°/nm. The narrower (wider) viewing angle means higher (less) percentage of light in the normal forward direction.

Second, the measured EL spectra of PlaCSH-OLED show being independent of the emission angle, namely, uniform color over angle (COA), highly desired in displays, just as ITO-OLED (referring to FIGS. 12a-12e). Again, the COA provides another experimental evidence of the omni radiation enhancement nature of PlaCSH. In previous light extraction enhancement approaches of replacing the ITO electrode with thin metal film(s) (e.g. dielectric-metal-dielectric (DMD) layers) or using dielectric resonant cavities, the LEDs have a poor COA. This indicates again that the PlaCSH is a fundamentally different type of cavity and is based on a different physical principle from previous approaches.

Third, while ITO-OLEDs having a Lambertian light emission distribution and hence an angle independent luminance (i.e. brightness), the luminance of the PlaCSH-OLED can become angle dependent. For the 80 nm cavity length PlaCSH-OLED (having 100 o viewing angle), the luminance at the normal angle (which is the most relevant angle to the displays for hand-held devices) is 13,000 cd/m2 at 10 mA/cm2 and 65,000 cd/m2 at 75 mA/cm2, which is 1.78 and 1.86 fold brighter than the ITO-OLED (7,300 cd/m2 and 35,000 cd/m2) (referring to FIGS. 4a-4b). These enhancements come from 1.57 fold higher light extraction (hence EQE) and 1.17 fold viewing angle narrowing (more light in the forwarding direction).

Broad Band, High, Omni Absorption (Low Reflection) to Ambient Light

The absorptions (reflections) of ambient light by the LEDs were measured with a white light source as well as the light standard, collimation optic, and spectrometer similar to the previously described. A striking feature of PlaCSH-OLEDs is that the absorption (hence reflection) to ambient light is not only much higher (lower) than ITO-OLEDs. More importantly, it is broadband, and nearly angle and polarization independent up to 30° and afterward a dependence far less than that predicted by Fresnel's law (which is termed “Omni acceptance”), making it have far less glare and higher contrast.

Specifically, the ambient light reflectance spectra of OLEDs measured at normal incident and 300 to 900 nm wavelength range show (1) the PlaCSH-OLEDs have a minimum reflectance of 8.3% at 720 nm wavelength, an average of 26%, and luminous reflectance of 25% (average over the luminosity function and CIE standard illuminant D65, see below), which is, respectively, 5.6, 2.8, and 2.7 fold smaller than that of the ITO-OLEDs (a minimum reflectance of 45% at 450 nm, an average of 70%, and a luminous reflectance of 67%); and (2) the bandwidth for the low ambient light reflection (high absorption) is 400 nm for PlaCSH-OLEDs—4.4 fold wider than 90 nm for ITO-OLEDs. The ambient light absorption/reflection properties are also clearly seen in the photographs of the PlaCSH and ITO-OLEDs taken at normal direction under white light (FIGS. 5H-5I). FIGS. 5H-5I show photographs at the same scale.

The luminous reflectance in the paper was calculated by:

$${R}_{L} = \frac{{\int }_{{λ}_{2}}^{{λ}_{1}} V ( λ ) S ( λ ) R ( λ ) d λ}{{\int }_{{λ}_{1}}^{{λ}_{2}} V ( λ ) S ( λ ) d λ}$$

where V(λ) is the standard photonic curve (eye's luminosity function), S(λ) is the CIE standard illuminant D65, R(λ) is the reflective spectrum, λ1 and λ2 are chosen as 450 and 750 nm.

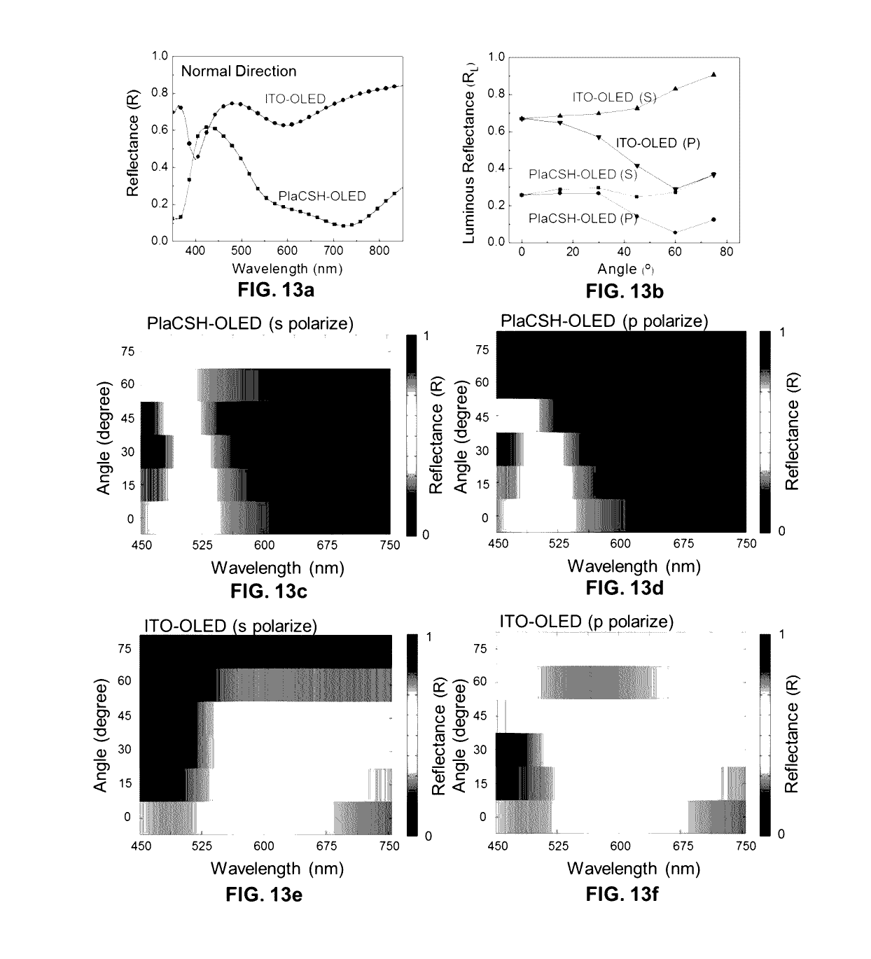

FIGS. 12a-12f depict measured angle and polarization dependence of ambient light reflectance for PlaCSH-OLEDs and ITO-OLEDs. FIG. 13a depicts reflectance spectra at normal incidence. FIG. 13b depicts luminous reflectance over 450 nm-750 nm wavelength range vs. incident angle. FIG. 13c depicts reflectance vs. wavelength for s-polarization for PlaCSH-OLEDs. FIG. 13d depicts reflectance vs. wavelength for p-polarization for PlaCSH-OLEDs. FIG. 13e depicts reflectance vs. incident angle for s-polarization for ITO-OLEDs. FIG. 13f depicts reflectance vs. incident angle for p-polarization for ITO-OLEDs. Experiments show that (i) the normal luminous reflectance of PlaCSH-OLEDs is 25%, which is 3 times smaller than ITO-OLED (67%), and (ii) the glare (reflectance from angles) of PlaCSH-OLED is not only over 3 fold smaller than ITO-OLED, but more importantly nearly independent of light polarization and incident angle, (termed “Omni glare”). For example, at 60o, the luminous reflectance of PlaCSH-OLED is about 3.1 and 5.8 fold smaller than ITO-LED for s and p-polarization (27%: 83%, 5%: 29%), respectively.

The ambient light luminous reflectances of OLEDs measured at different angle and polarization show that the luminous reflectances of the PlaCSH-OLEDs are not only much smaller than the ITO-OLEDs, but more importantly, they do not follow Fresnel's law as ITO-OLEDs. Specifically, for the PlaCSH-OLEDs, the s-polarization reflectance is nearly constant at 27% for 0° to 60° angle and then is increased to 37% at 75°. The p-polarization reflectance is nearly constant at 27% for 0° to 30° angle, then drops with angle, reaching a minimum of 5% at 60o and 10% at 75° (referring to FIG. 13b). The s and p-polarization reflectance of PlaCSH-OLED at 60° angle is 3.1 and 5.8 fold less than ITO-OLED (27%:83%, 5%:29%), respectively; and is 2.5 and 3.1 fold less (37%:91%, 12%:37%) at 75° angle. The broadband, omni high ambient light absorption (low reflection) of PlaCSH-OLEDs also can be seen in the 3D plots of the reflection as a function of both angle and polarization (referring to FIGS. 12c-12f). The ambient light absorption properties of PlaCSH-OLEDs are similar to the PlaCSH-photovoltaic devices that were reported previously.

Omni Radiation and Absorption Enhancement, EQE-Absorptance Product

In the experiments described above, the enhancement of light radiation and absorption by PlaCSH were measured separately and independently. Thus, the experiments provide the first direct experimental proof that the plasmonic nanocavity, PlaCSH-OLED, is excellent in both light radiation and absorption over broad wavelength band and nearly independent of incident angle and polarization (omni radiation/acceptance enhancement) (e.g. both excellent optical antenna and optical absorber). The product of LED's EQE and ambient-light-absorptance (EQE-A), a key figure of merit to a display, is 0.21 (29%×74%) and 0.41 (55%×74%) for the PlaCSH-OLEDs without or with a lens, which is at least 3 fold higher than all previous LEDs.

High Contrast of PlaCSH-OLED

The high light extraction and low ambient light reflection of PlaCSH-OLED lead to a significant enhancement of the contrast, which is defined as:

Contrast=(Lₒₙ+L_{ambient}×R_{L})/(L_{off}+L_{ambient}×R_{L})

where Lₒₙ and L_{off} is the luminance of the “on” and “off” state, respectively. L_{ambient} is the ambient luminance, and R_{L} is the luminous reflectance.

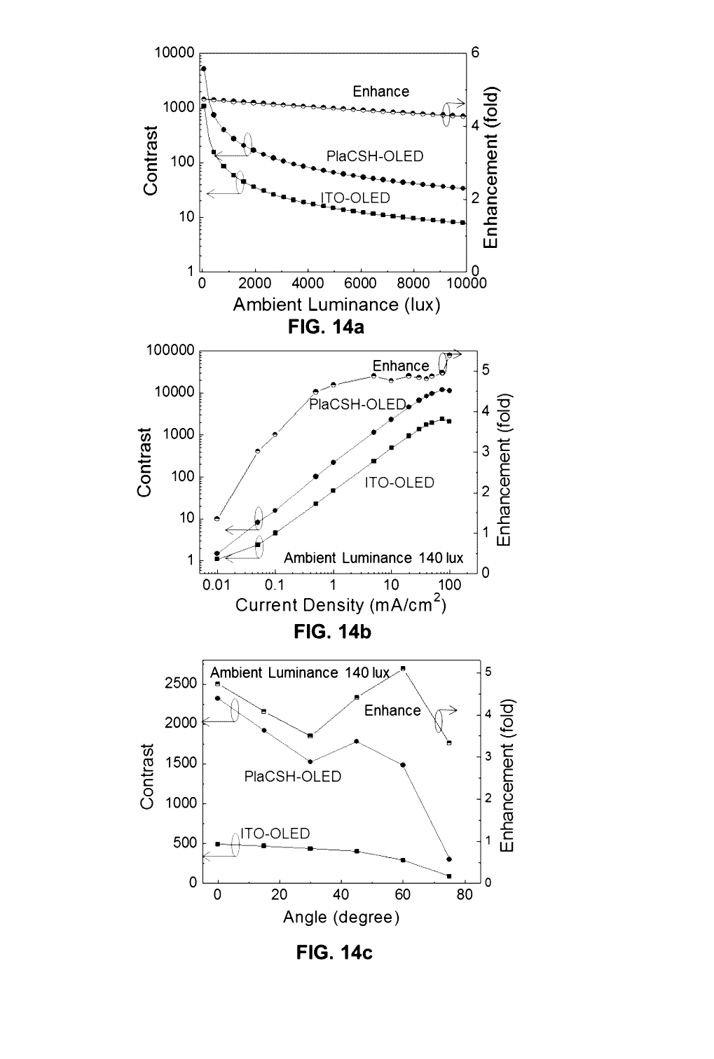

FIGS. 13a-13c depict measured contrast of PlaCSH-OLEDs, ITO-OLEDs and DMD-OLEDs in accordance with various disclosed embodiments. FIG. 14a depicts contrast versus ambient luminance at zero viewing angle. FIG. 14b depicts contrast versus current density. FIG. 14c depicts contrast versus viewing angle of PlaCSH-OLED and ITO-OLED. Unless specified, all ambient luminance are at 140 lux and all OLEDs have 10 mA/cm² current density. Experiments show that PlaCSH-OLED's contrast is about 4-5 times higher than ITO-OLED.

From the example, it was found that, for an ambient luminance range of 0 to 10,000 lux, and a current density range of 1 to 100 mA/cm², the contrast (average all polarizations) of PlaCSH-OLED is higher than the ITO-OLED by 4-5 fold for normal incident ambient light, and 3-5 fold for non-normal angle angles (FIGS. 13a-13c and Table 2).

For example, at the current 10 mA/cm², the PlaCSH-OLED has a contrast at 0° angle of 2,300, 330 and 34 respectively for an ambient luminance of 140 lux (typical, family living room), 1,000 lux (high, over cast day), and 10,000 lux (full daylight), respectively. All of the contrast values are 4-5 times higher than the ITO-OLED (490, 69 and 8). At the current 75 mA/cm², the contrasts of PlaCSH-OLED are further enhanced to 12,000, 1,600, and 160 for these three typical ambient luminances (Table. 2). For different current (1, 10, and 100 mA/cm²), the contrast of PlaCSH-OLED at 0° angle and 140 lux ambient luminance is 222, 2,300 and 11,324, which is also about 5 fold higher than ITO-OLED (48, 490, and 2,102) (FIG. 4 b). For a different angle of 0°, 30°, 60° and 75° and at 10 mA/cm² current and 140 lux ambient light, the contrast of PlaCSH-OLED reaches 2300, 1523, 1483 and 300, respectively which is 4.7, 3.5, 5.1, and 3.3 fold higher than ITO-OLED (490, 436, 291 and 90). The 5 fold higher contrast in PlaCSH-OLEDs comes from the 3 fold in the lower reflection and the 1.6 fold in the higher EQE/light extraction. The PlaCSH-OLED's ambient light absorption and contrast are also, based simulations, many times better than OLED structures with the dielectric/metal/dielectric front electrode (Ta₂O₅ (70 nm)/Au (18 nm)/MoO₃ (1 nm)) and an Al back electrode.

Simulations and Origin of Enhancements

Using a commercial finite-difference time-domain solver and the geometries, structures and indices of the LEDs from the experiments (except the light emitting material's index has only the real part and hence no absorption), we simulated the PlaCSH-OLED's radiation properties by putting electrical dipole oscillators inside the LEDs, and the absorption properties by sending a plane wave toward the LEDs. The simulated cavity length effects on the OLED's light radiation angle distributions (therefore the viewing angles) are consistent with the experiments within 5% (FIGS. 10b-10c), hence indicating the simulation meaningful.

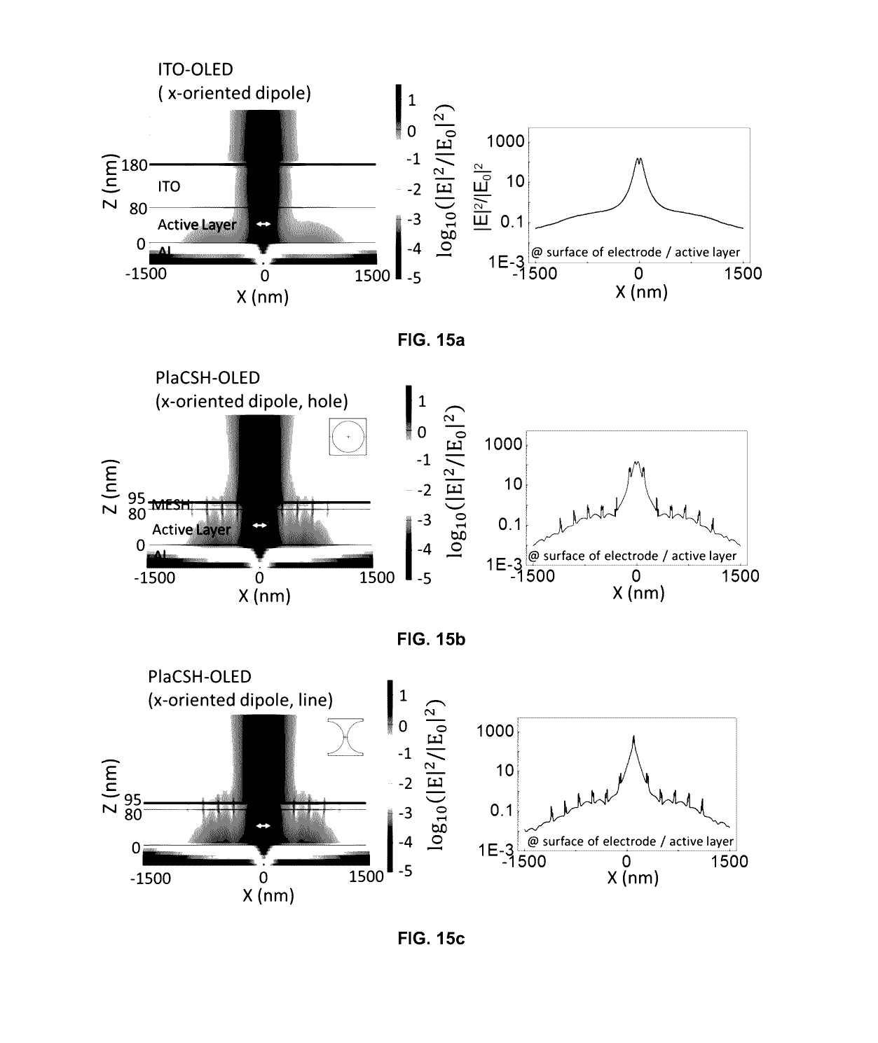

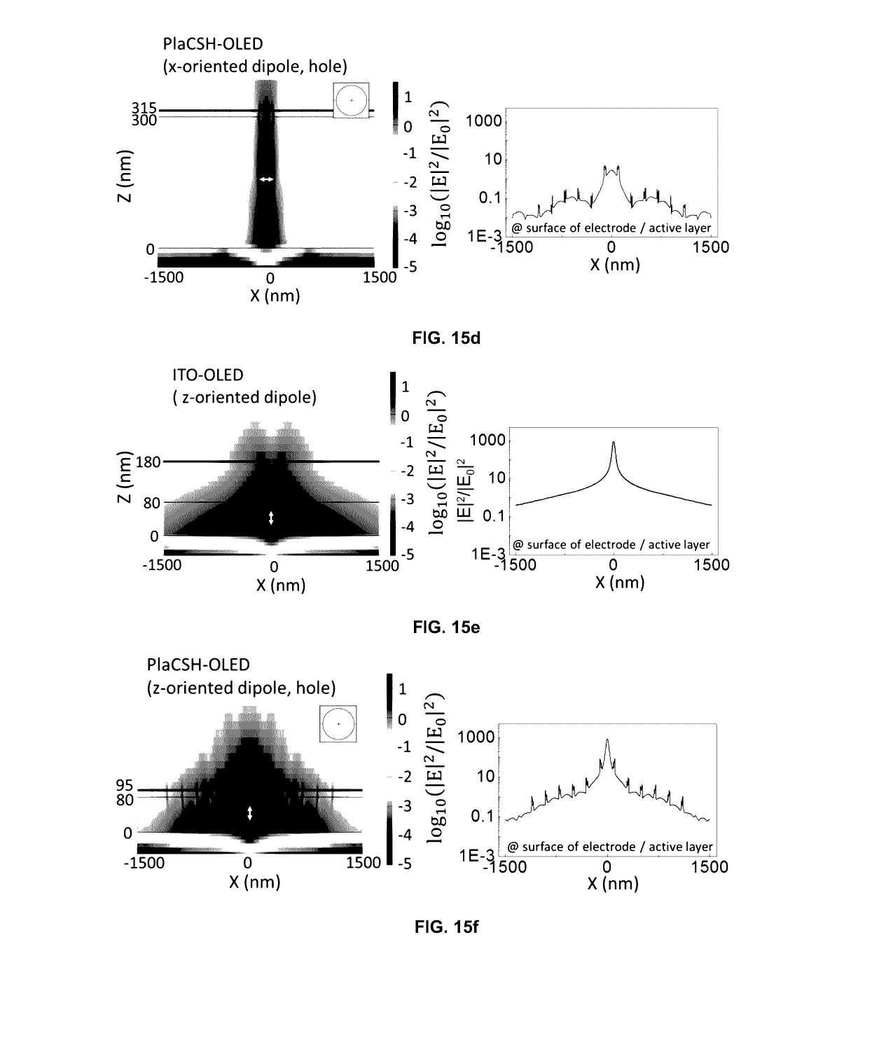

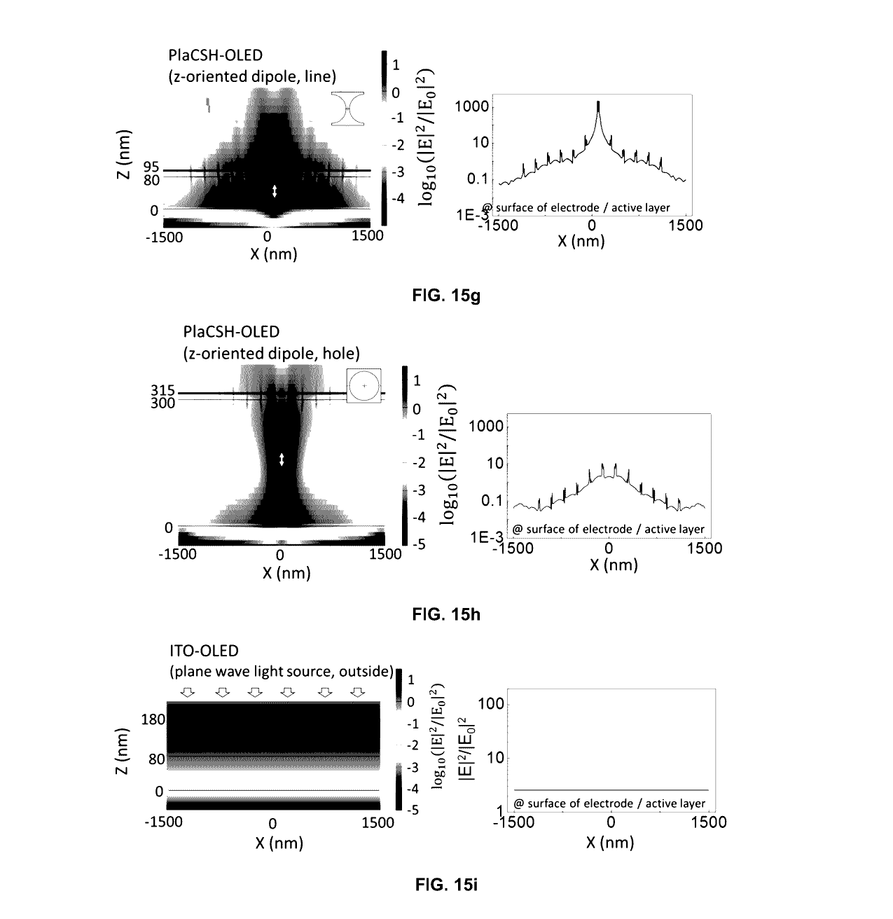

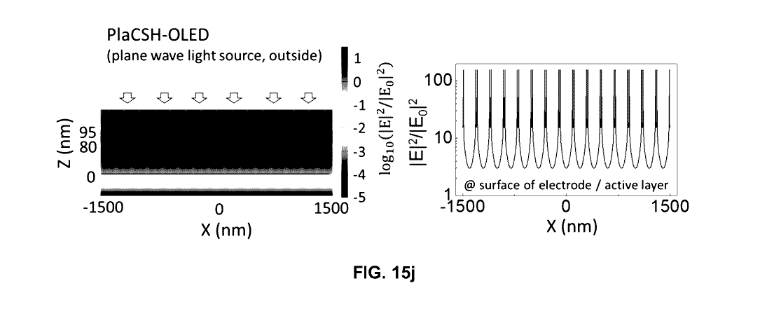

FIGS. 14a-14j depict numerical study of radiation and absorption properties of PlaCSH-OLED and ITO-OLED in accordance with various disclosed embodiments. FIGS. 14a-14j show E-field intensity distributions on a plane that is normal to the LED's layers and cuts through the center of the open-holes and grid-wire of the MESH (2D) and at the surface of the electrodes and active layer (1D). FIG. 15a depicts E-field intensity distributions in an ITO-OLED (80 nm thick active layer) with x-oriented dipole. FIG. 15b depicts E-field intensity distributions in PlaCSH-OLED (80 nm thick active layer) with x-oriented dipole located at a hole. FIG. 15c depicts E-field intensity distributions in PlaCSH-OLED (80 nm thick active layer) with x-oriented dipole located at a grid (i.e., a position on the top metallic layer that separates two adjacent holes). FIG. 15d depicts E-field intensity distributions in PlaCSH-OLED with 300 nm thick active layer (dipole at hole). FIGS. 14e-14h depict the same E-field intensity distributions as FIGS. 14a-14d, respectively, except that dipoles are z-oriented in FIGS. 14e-14h. In FIGS. 14a-14h, all dipoles are in the middle of the light-emitting layer. FIGS. 14i-14j respectively depict E-field intensity distributions of ITO-OLED and PlaCSH-OLED (80 nm thick active layer) excited by a plane wave light source outside the LEDs. In all of FIGS. 14a-14j, the black lines show the interface of different layers of materials. The bold line is the boundary of devices and substrate.

FIGS. 14a-14j show the simulated radiation of one single dipole 0=520 nm) positioned in the middle plane of the light emitting material layer and at a point that is under the middle of either an open-hole or a metal wire of the MESH. The simulations clearly show that the origin of the unique properties of PlaCSH-LEDs (enhancements in LED's light extraction, low-glare, contrast, viewing angle and brightness) is the localized surface plasmon-polaritons (SPP) generated in PlaCSH.

The simulations show that the PlaCSH is an excellent optical antenna, which radiates the light inside the cavity to outside efficiently (FIGS. 14a-14j). Particularly, the simulations show (a) unlike the electric field in ITO-OLED which decays monotonically with the distance (as expected for a dipole radiation), the electric field in PlaCSH-OLED is strongly modulated by the periodic metallic nanostructures of MESH, which have much higher electric field near the metal parts than the hole regions of MESH, indicating the dipole radiation being coupled into the SPP of the cavity (the SPP wavelength being determined by the MESH period); (b) the SPP in the MESH is localized around the dipole, since not all metal structures but 10-12 periods have a high electrical field; (c) the far-field average electric field is relative insensitive to the dipole's locations, indicating again the dipole radiation being coupled into the SPP; and (d) the 80 nm cavity length has much stronger radiation to outside than the 300 nm cavity length, indicating strong coupling with a subwavelength cavity length is essential to good light extraction.

For the absorption properties, the simulations further show the PlaCSH is an excellent light absorber for absorbing the light from outside into the PlaCSH cavity efficiently, which is another key feature of an excellent optical antenna. Particularly, the simulations show (a) the ITO-OLED reflects backward the most of the incident light (plane wave) and has only a small portion entered inside the cavity, but the PlaCSH-OLED has most of the incident light entered and trapped inside the cavity and has a very small reflection, even though the PlaCSH has the identical reflective metal backplane; and (b) the electric field is uniform in lateral direction (x-direction) in ITO-OLED, but modulated (with the same periodicity as MESH) in PlaCSH-OLED, indicating also the generation of SPP in PlaCSH. The simulations confirm that PlaCSH can be a good light radiator and absorber at the same time.

The PlaCSH-OLED's radiation and absorption behaviors were also simulated in other wavelengths (from 480 to 640 nm range), and were found to be nearly independent of the wavelength, hence broadband.

Further Discussions

By using open-market-available organic light-emitting materials, the PlaCSH-OLEDs can demonstrate (1) high light emission: light extraction efficiency (without or with a lens) of 32% and 60%, which are so far the highest achieved for a 1.46 index substrate and any substrate with a scaled index, and 1.57 fold higher than the same LEDs except an indium-tin-oxide front-electrode (ITO-OLEDs), and an external quantum efficiency of 29% and 55% (without or with a lens); (2) high, broad-band, Omni (nearly angle and polarization independent) absorption to ambient light from outside the cavity, leading to 25% luminous reflectance over 400 nm bandwidth, which is 2.7 fold smaller than the ITO-OLEDs; (3) because of (1) and (2), a contrast of 5 and 3 fold, respectively, higher than the ITO-OLEDs and the OLED with a dielectric-metal-dielectric front electrode; (4) a viewing angle tunable by the cavity length (about 1°/nm tenability), exhibiting up to 17 o narrower or wider than the ITO-OLEDs of a nearly-fixed viewing angle; (5) a normal-view brightness of 1.79 fold higher than ITO-OLED, and (6) uniform color over all emission angles.

From the experiments and simulations in the example as disclosed above, the unique advantages of PlaCSH-OLEDs can be due to the unique properties of the PlaCSH structure over other existing LED structures. Previous LED structures (i.e., non-resonant cavity structure) cannot be a good light radiator and absorber at the same time; and dielectric resonant-cavity LEDs can be a good light radiator and absorber only in a few nanometer wavelength range and in a particular direction; hence, incapable of enhancing all the critical factors for display applications. On the other hand, PlaCSH is an excellent optical antenna that is an excellent light radiator and absorber over broad wavelength band and for nearly all light incident angles and polarizations. Thus, PlaCSH can lead to enhancements of all critical factors of displays. Such unique properties maybe attributed to surface plasmonic polariton generation, lateral plasmonic momentum fixed by the periodic structure, and the wavelength dependence of metal permittivity.

As described in various embodiments as above, compared to the conventional OLEDs (the same but without PlaCSH), a PlaCSH-OLEDs can achieve experimentally: (i) 1.57 fold higher front-surface external quantum efficiency (EQE) and light extraction efficiency (29% and 32% without lens, 55% and 60% with lens)—among the highest reported; (ii) ambient light absorption not only 2.5 fold higher (92% max, 74% average), but also broad-band (400 nm) and nearly angle and polarization independent up to 30o and then much smaller changes than Fresnel's law, leading to lower glare; (iii) a contrast of 5 fold higher (12,000, 1,600, and 160 for 140, 1,000 and 10,000 lux ambient light) and the highest EQE-absorption-product over previous LEDs; (iv) a viewing angle tunable by the cavity length—either narrower or wider than Lambertian (38° tunability demonstrated); (v) 1.86 fold higher normal-view brightness (65,000 cd/m2 luminance at 75 mA/cm2); (vi) 8 ohm/sq sheet-resistance—20% lower; and (vii) uniform color over all emission angles. Therefore, PlaCSH LEDs can significantly enhance light extraction, contrast, brightness, and low-glare without sacrificing image sharpness.

In comparison, conventional LEDs may often enhance the light extraction while sacrificing the contrast and image sharpness, and may often enhance contrast while sacrificing luminance. The simulations as described in certain embodiments above further confirm that indeed the PlaCSH may function as an excellent optical antenna that can be excellent both radiation and absorption of light, i.e. radiating the light inside the cavity to outside efficiently and absorbing the light from outside into the cavity efficiently.

Furthermore, PlaCSH-LEDs or PlaCSH-OLEDs, can include a simple structure for fabrication process. The structure can be fabricated using nanoimprint over large area (up to 1,000 cm²), hence scalable to wallpaper size. Thus, PlaCSH-LEDs or PlaCSH-OLEDs, can be produced at reduced manufacturing cost and increased yield. PlaCSH-OLED's performances can be further improved with optimized structures and materials.

In addition, because of replacing the ITO electrode with MESH and having a total thickness less than 200 nm, PlaCSH-OLEDs can be flexible and ductile, and can be potentially made into a fiber form. PlaCSH-OLEDs have already being fabricated by low-cost nanopatterning, nanoimprint to large area (up to 1,000 cm²), hence scalable to wallpaper size. PlaCSH-OLED's performances can be further optimized by adjusting materials, structures, or substrate index, the above. The designs, fabrications, and findings are applicable to the LEDs having various light-emitting materials (organic or inorganic) and on various thin substrates (plastics or glasses).

Various embodiments further provide a display panel. The display panel can include one or more PlaCSH-LEDs as disclosed in various embodiments. Various embodiments further provide a method for forming a display panel. The method can include the processses as disclosed in various embodiments, e.g., as shown in FIGS. 1 and 2A-2F.

Various embodiments further provide an electronic device. The display panel can include one or more PlaCSH-LEDs as disclosed in various embodiments. The electronic device can include any of televisions, computers, tablet devices, smart phones, feature phones, personal digital assistants, and the like. The electronic device can have a display panel that includes one or more PlaCSH-LEDs as disclosed in various embodiments.

Various embodiments further provide a method for forming an electronic device. The method can include the processes as disclosed in various embodiments, e.g., as shown in FIGS. 1 and 2A-2F.

Further, a display panel formed using PlaCSH-LED can also be integrated with various other electronic components for more functionalities. For example, a display panel formed using PlaCSH-LED can also be integrated with a touch panel to form a touch screen to be used in the above-mentioned applications. In various applications, when used as light emitting diode, the incident emission light might not necessarily illuminate in/from the direction normal to the cavity surface, and instead can be in/from the direction with certain angle (0 to 90 degree) to the cavity surface, especially in/from the side slit (vertical section) of the cavity.

As PlaCSH-LED being a good light absorber, display formed using PlaCSH-LED can also be integrated with battery. PlaCSH-LED can be used as a photovoltaic device to charge the battery to store electricity. The electricity in the battery can subsequently be used for operating the display to emitting light (solar/ambient-light powered display). For example, an electronic product can have a first PlaCSH-LED panel as a charging panel, and have a second PlaCSH-LED panel as a display panel. The first PlaCSH-LED panel and the second PlaCSH-LED panel can be separate panels or one integrated panel. Even when the first PlaCSH-LED panel and the second PlaCSH-LED panel are separate panels, manufacturing process can be simplified because same or similar materials and techniques can be used for making both panels and fabrication steps may be simplified.

As used herein, relational terms such as ‘first’ and ‘second’ are merely used for differentiate one element or operation from another element or operation, and do not require or imply that any actual relationship or order as such exist between these elements or operations. In addition, the terms “include”, “comprise”, “contain”, or any other variations thereof, are intended to cover a non-exclusive inclusion, such that a process, method, article, or apparatus that includes a series of elements can not only include those elements, but also include other elements not expressly listed, or inherent elements for such a process, method, article, or apparatus. Without further limitation, an element defined by a statement “include one” does not exclude additional identical elements that may be included in the process, method, article, or apparatus that includes the element.

The embodiments disclosed herein are exemplary only. Other applications, advantages, alternations, modifications, or equivalents to the disclosed embodiments are obvious to those skilled in the art and are intended to be encompassed within the scope of the present disclosure.

### REFERENCE SIGN LIST

LED 10
Plasmonic cavity with subwavelength hole-array 12
Cavity length 13
MESH layer 14
Backplane layer 16
Light-emitting material layer 18
Photons 21
First interface layer 22
Second interface layer 24
Incident photons 25
Electric lead 26
Reflected photons 27
Electric lead 28
Substrate 30
Metallic material disk array 40
Disk 42
Distance 44
Single material 52
Materials mixture 54
Multi-layer stacking structure 56
Metallic material layer 60
Metallic material film 62
Holes (or apertures) 64

What is claimed is:

1. A light-emitting diode (LED), comprising:
a photonic resonant cavity antenna comprising:
(a) a top metallic layer that is light transmissive and has a lateral structure smaller than wavelength of the light;
(b) a bottom metallic layer; and
(c) a light emitting material layer of semiconductor positioned between the top metallic layer and the bottom metallic layer for generated light
whereas the generated light transmitted through the top metallic layer, and whereas the LED has a low reflection to an ambient light, improved light generation in the cavity and/or improved light transmission to outside the cavity, and improved contrast.

2. The light-emitting diode according to claim 1, wherein a plural of light emitting diodes forms a display.

3. The light-emitting diode according to claim 1, wherein a plural of light emitting diodes forms a camera with each LED as one pixel.

4. The light-emitting diode according to claim 1, wherein a plural of light emitting diodes forms an array of photodetectors/photovoltaic device.

5. The light-emitting diode according to claim 1, wherein a plural of light emitting diodes operates in both light emitting mode and photon detection mode for imaging or supper supply.

6. The light-emitting diode according to claim 1, wherein the wavelength of the light ranges from about 100 nm to about 10,000 nm.

7. The light-emitting diode according to claim 1, wherein the top metallic layer comprises a metal mesh with one or more apertures in the top metallic layer.

8. The light-emitting diode according to claim 7 wherein the one or more apertures have a shape selected from a group including round, rectangle, polygon, triangle, and a superposition thereof.

9. The light-emitting diode according to claim 7, wherein the apertures have an aperture size of less than a wavelength of the light.

10. The light-emitting diode assembly according to claim 1, wherein the top metallic layer comprises one or a plural of metallic disks.

11. The light-emitting diode assembly according to claim 9, wherein the shape of the disks has a the shape selected from a group including round, rectangle polygon, and triangle, and a superposition thereof, and the disk has a lateral dimension less than a wavelength of the light.

12. The light-emitting diode according to claim 1, wherein the top metallic layer or the backplane layer is made of a material selected from a group comprising gold, copper, silver, aluminum, titanium, platinum, an alloy made of one or more metals thereof, a mixture of one or more metals thereof, and a multi-layer stacking structure thereof.

13. The light-emitting diode according to claim 1, wherein the top metallic layer forms an electrode for supplying electrical current to the light-emitting material layer.

14. The light-emitting diode according to claim 1 wherein the top metallic layer has a thickness ranging from about 1 nm to about 100 nm.

15. The light-emitting diode according to claim 1, further comprising:
a first interface layer disposed between the top metallic layer and the light-emitting material layer; and
a second interface layer disposed between the backplane layer and the light-emitting material layer.

16. The light-emitting diode of claim 1, wherein the light-emitting material layer is made of a material including a semiconductor that emits photons under an electric current.

17. The light-emitting diode of claim 14, wherein the light-emitting material layer includes one or more of a single material, a mixture of a plurality of materials, a multi-layer stacking structure of a plurality of materials, a p-n junction, or a combination thereof.

18. The light-emitting diode of claim 14, wherein the light-emitting material layer is a semiconductor selected from a group consisting of crystal, amorphous, polycrystalline, inorganic, organic, a polymer, Gallium Arsenide (GaAs), Gallium Nitride (GaN), Silicon (Si), Germanium (GE), and their mixtures, multilayers, and alloys.

19. The light-emitting diode according to claim 14, wherein the light-emitting material layer is one or more organic semiconductors.

20. The light-emitting diode according to claim 14, wherein the light-emitting material layer has a thickness ranging from about 2 nm to about 700 nm.

21. The light-emitting diode assembly according to claim 14, wherein the light-emitting material layer has a thickness ranging from about 1 nm to about 100 nm.

22. The light-emitting diode according to claim 1, wherein the photonic resonant cavity antenna has one or more of the following characteristics:
improving production of a light produced in the light-emitting material layer and produced outwardly from the light-emitting diode; and
improving efficiency of the light emitting diode to absorbing ambient light.

23. A method for forming a light-emitting diode (LED), comprising:
forming a metallic-mesh electrode with subwavelength hole-array (MESH) layer that is transmissive to a light emitted by the LED and that has at least one lateral structure smaller than a wavelength of the light;
forming a backplane layer; and
forming a light-emitting material layer positioned between the top metallic layer and the backplane layer, wherein the light-emitting material layer is grown by using at least one of low temperature molecule beam epitaxy and thin film deposition.

24. The method according to claim 23, wherein the forming of the top metallic layer is fabricated by at least one method selected from a group comprising electron beam lithography, ion beam lithography, optical lithography, and self-assembly.

25. The method according to claim 23, wherein the forming of the top metallic layer comprises transfer printing.

26. The method according to claim 23, wherein the forming of the top metallic layer comprises nanoprinting.
